(19) United States
(12) Patent Application Publication
(10) Pub. No.: US 2016/0333188 A1
(43) Pub. Date: Nov. 17, 2016

(54) HYDROPHOBIC FLUORINATED COATINGS

(71) Applicant: 3M INNOVATIVE PROPERTIES COMPANY, St. Paul, MN (US)

(72) Inventors: Justin A. Riddle, St. Paul, MN (US); Naiyong Jing, St. Paul, MN (US); Erik D. Olson, St. Louis Park, MN (US); Karl J. Manske, St. Anthony, MN (US); Richard M. Flynn, Mahtomedi, MN (US); Suresh S. Iyer, Woodbury, MN (US)

(21) Appl. No.: 15/219,442

(22) Filed: Jul. 26, 2016

Related U.S. Application Data
(63) Continuation of application No. 13/883,385, filed on May 3, 2013.
(60) Provisional application No. 61/497,350, filed on Jun. 15, 2011.
(60) Provisional application No. 61/412,134, filed on Nov. 10, 2010.

(51) Int. Cl. C09D 5/00; C09D 7/12; C23C 16/44; C09D 183/08

(52) U.S. Cl. CPC C09D 5/00; C09D 183/08; C09D 7/1216; C09D 5/002; C23C 16/44

(57) ABSTRACT

Articles having hydrophobic fluorinated coatings are provided. More specifically, the articles include a substrate, a primer layer of acid-sintered silica nanoparticles, and a hydrophobic fluorinated layer. The hydrophobic fluorinated coatings can be used on a large variety of substrate and tend to be quite durable even when subjected to repeated rubbing and/or cleaning.

### CROSS REFERENCE TO RELATED APPLICATIONS

This application is a continuation application of pending prior application Ser. No. 13/883,385, filed May 3, 2013, which is a national stage filing under 35 U.S.C. 371 of PCT/US2011/059570, filed Nov. 7, 2011, which claims priority to U.S. Provisional Applications 61/497,350, filed Jun. 15, 2011 and 61/412,134, filed Nov. 10, 2010, the disclosures of which are incorporated by reference in their entireties herein.

### FIELD

Articles and methods of making articles having hydrophobic fluorinated coatings are provided.

### BACKGROUND

Various compositions of fluorochemical materials have been applied to surfaces to impart low surface energy characteristics such as oil and/or water repellency (oleophobicity and/or hydrophobicity). When used in coatings, however, many fluorochemical materials have tended to become depleted over time especially when the surfaces have been subjected to repeated cleaning or rubbing.

Silane compounds having one or more fluorochemical groups (e.g., perfluoroalkyl, perfluoroether, and perfluoropolyether groups) have been used to provide coating compositions to substrates such as glass and ceramic materials. Such Silane compounds include those, for example, described in U.S. Pat. No. 3,950,588 (McDougal), U.S. Pat. No. 7,335,786 (Iyer et al.), U.S. Pat. No. 7,745,653 (Iyer et al.), and U.S. Patent Application Publication No. 2010/0167978 (Iyer et al.).

### SUMMARY

Articles having hydrophobic fluorinated coatings are provided. More specifically, the articles include a substrate, a primer layer of acid-sintered silica nanoparticles attached to a surface of the substrate, and a hydrophobic fluorinated layer attached to the primer layer. Due to the presence of the primer layer, the hydrophobic fluorinated layer can be indirectly attached to a large variety of substrates. The primer layer and the hydrophobic fluorinated layer combine to provide a hydrophobic coating that can be quite durable even when subjected to repeated rubbing and/or cleaning. The articles typically have surfaces that are easy to clean, smudge resistant, and fingerprint resistant.

In a first aspect, an article is provided that includes (a) a substrate, (b) a primer layer attached to a surface of the substrate, and (c) a hydrophobic fluorinated layer attached to the primer layer. The primer layer contains a plurality of acid-sintered silica nanoparticles arranged to form a continuous three-dimensional porous network. The hydrophobic fluorinated layer contains the reaction product of a fluorinated silane with a surface of the acid-sintered silica nanoparticles in the primer layer. The fluorinated silane contains both a reactive silyl group and a hydrophobic fluorinated group (e.g. a hydrophobic perfluorinated group).

In many embodiments, the fluorinated silane used to form the hydrophobic fluorinated layer of the article is of Formula (I).

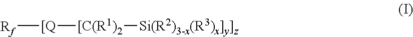

In Formula (I), group R_{f} is a z-valent radical of a perfluoroether, perfluoropolyether, or perfluoroalkane. Group Q is a single bond, a divalent linking group, or trivalent linking group. Each group R¹ is independently hydrogen or alkyl. Each group R² is independently hydroxyl or a hydrolyzable group. Each group R³ is independently a non-hydrolyzable group. The variable x is an integer equal to 0, 1, or 2. The variable y is an integer equal to 1 or 2. The variable z is an integer equal to 1 or 2.

In a second aspect, a method of making an article is provided. The method includes providing a substrate and forming a primer layer on a surface of the substrate. The primer layer contains a plurality of acid-sintered silica nanoparticles arranged to form a continuous three-dimensional porous network. The method further includes covalently bonding a hydrophobic fluorinated layer to the primer layer by reacting a surface of the acid-sintered silica nanoparticles in the primer layer with a fluorinated silane. The fluorinated silane contains both a reactive silyl group and a fluorinated group (e.g., a perfluorinated group). In many embodiments, the fluorinated silane used to form the hydrophobic fluorinated layer is of Formula (I).

### BRIEF DESCRIPTION OF THE DRAWINGS

FIG. 1A is a transmission electron micrograph of a comparative example primer layer formed without acid-sintering of the silica nanoparticles. FIG. 1B is a transmission electron micrograph of an exemplary primer layer formed using acid-sintered silica nanoparticles.

### DETAILED DESCRIPTION

Articles having hydrophobic coatings are provided. More specifically, the articles include a substrate, a primer layer of acid-sintered silica nanoparticles, and a hydrophobic fluorinated layer that is covalently bonded to the primer layer. The primer layer is positioned between the substrate and the hydrophobic fluorinated layer. The hydrophobic fluorinated layer is formed from a fluorinated silane that contains both a reactive silyl group and a fluorinated group (e.g., a perfluorinated group). The fluorinated silane is covalently bonded to the primer layer through a reaction of the reactive silyl group with a surface of the acid-sintered silica nanoparticles in the primer layer resulting in the formation of a —Si—O—Si— bond between the primer layer and the hydrophobic fluorinated layer.

The hydrophobic coatings, which are a combination of the primer layer and the hydrophobic fluorinated layer, tend to be quite durable even when subjected to repeated rubbing and/or cleaning. A variety of substrates can be used including those that traditionally have not been used with fluorinated silanes because the substrates lack a group capable of reacting with the silyl group of the fluorinated silanes. The surface of the substrate can be altered to become hydrophobic or more hydrophobic through treatment with the primer layer and the reaction of the fluorinated silane with the primer layer. The hydrophobic coatings tend to provide a surface that is easy to clean, smudge resistant, and fingerprint resistant.

The recitation of any numerical range by endpoints is meant to include the endpoints of the range, all numbers within the range, and any narrower range within the stated range.

The term “a”, “an”, and “the” are used interchangeably with “at least one” to mean one or more of the elements being described.

The term “and/or” means either or both. For example, the expression “A and/or B” means A, B, or a combination of A and B.

The term “alkyl” refers to a monovalent group that is a radical of an alkane and includes groups that are linear, branched, cyclic, bicyclic, or a combination thereof. The alkyl group typically has 1 to 30 carbon atoms. In some embodiments, the alkyl group contains 1 to 20 carbon atoms, 1 to 10 carbon atoms, 1 to 6 carbon atoms, 1 to 4 carbon atoms, or 1 to 3 carbon atoms.

The term “alkylene” refers to a divalent group that is a radical of an alkane and includes groups that are linear, branched, cyclic, bicyclic, or a combination thereof. The alkylene group typically has 1 to 30 carbon atoms. In some embodiments, the alkylene group has 1 to 20 carbon atoms, 1 to 10 carbon atoms, 1 to 6 carbon atoms, or 1 to 4 carbon atoms.

The term “alkyleneoxy” refers to a divalent group that is an oxy group bonded directly to an alkylene group.

The term “alkoxy” refers to refers to a monovalent group having an oxy group bonded directly to an alkyl group.

The term “aryl” refers to a monovalent group that is aromatic and carbocyclic. The aryl has at least one aromatic ring and can have one or more additional carbocyclic rings that are fused to the aromatic ring. Any additional rings can be unsaturated, partially saturated, or saturated. Aryl groups often have 6 to 20 carbon atoms, 6 to 18 carbon atoms, 6 to 16 carbon atoms, 6 to 12 carbon atoms, or 6 to 10 carbon atoms.

The term “arylene” refers to a divalent group that is aromatic and carbocyclic. The arylene has at least one aromatic ring and can have one or more additional carbocyclic rings that are fused to the aromatic ring. Any additional rings can be unsaturated, partially saturated, or saturated. Arylene groups often have 6 to 20 carbon atoms, 6 to 18 carbon atoms, 6 to 16 carbon atoms, 6 to 12 carbon atoms, or 6 to 10 carbon atoms.

The term “aryloxy” refers to a monovalent group having an oxy group bonded directly to an aryl group.

The term “aralkyl” refers to a monovalent group that is an alkyl group substituted with an aryl group. Aralkyl groups often have an alkyl portion with 1 to 10 carbon atoms, 1 to 6 carbon atoms, or 1 to 4 carbon atoms and an aryl portion with 6 to 20 carbon atoms, 6 to 18 carbon atoms, 6 to 16 carbon atoms, 6 to 12 carbon atoms, or 6 to 10 carbon atoms.

The term “aralkyloxy” refers to a monovalent group having an oxy group bonded directly to an aralkyl group. Equivalently, it can be considered to be an alkoxy group substituted with an aryl group.

The term “aralkylene” refers to a divalent group that is an alkylene group substituted with an aryl group or an alkylene group attached to an arylene group. Aralkylene groups often have an alkylene portion with 1 to 10 carbon atoms, 1 to 6 carbon atoms, or 1 to 4 carbon atoms and an aryl or arylene portion with 6 to 20 carbon atoms, 6 to 18 carbon atoms, 6 to 16 carbon atoms, 6 to 12 carbon atoms, or 6 to 10 carbon atoms.

The term “acyloxy” refers to a monovalent group of formula —O(CO)R^{b} where R^{b} is alkyl, aryl, or aralkyl. Suitable alkyl R^{b} groups often have 1 to 10 carbon atoms, 1 to 6 carbon atoms, or 1 to 4 carbon atoms. Suitable aryl R^{b} groups often have 6 to 12 carbon atoms such as, for example, phenyl. Suitable aralkyl R^{b} groups often have an alkyl group with 1 to 10 carbon atoms, 1 to 6 carbon atoms, or 1 to 4 carbon atoms that is substituted with an aryl having 6 to 12 carbon atoms such as, for example, phenyl.

The term “catenated heteroatom” refers to a heteroatom (e.g., oxygen, sulfur, or nitrogen) that replaces at least one carbon atom in a carbon chain. For example, ether groups contain one catenary oxygen atom with at least one carbon atom on each side of the catenary oxygen atom and polyether groups contain more than one catenary oxygen atom with carbon atoms on each side of the more than one catenary oxygen atoms.

The term “carbonyl” means a divalent group of formula —(CO)— where the carbon atoms is bonded to the oxygen with a double bond.

The term “carbonylimino” means a divalent group of formula —(CO)NR^{a}—, where R^{a} is hydrogen, alkyl, aryl, or aralkyl. Suitable alkyl R^{a} groups often have 1 to 10 carbon atoms, 1 to 6 carbon atoms, or 1 to 4 carbon atoms. Suitable aryl R^{a} groups often have 6 to 12 carbon atoms such as, for example, phenyl. Suitable aralkyl R^{a} groups often have an alkyl group with 1 to 10 carbon atoms, 1 to 6 carbon atoms, or 1 to 4 carbon atoms that is substituted with an aryl having 6 to 12 carbon atoms such as, for example, phenyl. The carbonylimino group can also be referred to interchangeably as an iminocarbonyl group. This group is sometimes referred to as an amido group.

The term “carbonyloxy” means a divalent group of formula —(CO)O—. The carbonyloxy group can be referred to interchangeably as an oxycarbonyl group.

The term “halo” refers to a halogen atom such as fluoro, bromo, iodo, or chloro. When part of a reactive silyl, the halo group is often chloro.

The term “iminocarbonylimino” refers to a divalent group of formula —R^{a}N—(CO)—NR^{a}— where R^{a} is hydrogen, alkyl, aryl, or aralkyl. Suitable alkyl R^{a} groups often have 1 to 10 carbon atoms, 1 to 6 carbon atoms, or 1 to 4 carbon atoms. Suitable aryl R^{a} groups often have 6 to 12 carbon atoms such as, for example, phenyl. Suitable aralkyl R^{a} groups often have an alkyl group with 1 to 10 carbon atoms, 1 to 6 carbon atoms, or 1 to 4 carbon atoms that is substituted with an aryl having 6 to 12 carbon atoms such as, for example, phenyl. This group is sometimes referred to as a ureylene group.

The term “oxycarbonyloxy” refers to a divalent group of formula —O(CO)O—. This group is sometimes referred to as a carbonate group.

The term “oxycarbonylimino” refers to a divalent group of formula —O—(CO)—NR^{a}— where R^{a} is hydrogen, alkyl, aryl, or aralkyl. Suitable alkyl R^{a} groups often have 1 to 10 carbon atoms, 1 to 6 carbon atoms, or 1 to 4 carbon atoms. Suitable aryl R^{a} groups often have 6 to 12 carbon atoms such as, for example, phenyl. Suitable aralkyl R^{a} groups often have an alkyl group with 1 to 10 carbon atoms, 1 to 6 carbon atoms, or 1 to 4 carbon atoms that is substituted with an aryl having 6 to 12 carbon atoms such as, for example, phenyl. This group can be referred to interchangeably as an iminocarbonyloxy group.

The term methine refers to a trivalent carbon group of formula

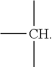

The methine group is bonded to three groups other than hydrogen and often functions as a branching point in a molecular chain.

The term “fluorinated” refers to a group or compound that contains at least one fluorine atom attached to a carbon atom. Perfluorinated groups, in which there are no carbon-hydrogen bonds, are a subset of fluorinated groups.

The term “perfluorinated group” refers to a group having all C—H bonds replaced with C—F bonds. Examples include monovalent or divalent radicals of a perfluoropolyether, perfluoroether, or perfluoroalkane.

The term “perfluoroether” refers to ether in which all of the C—H bonds are replaced with C—F bonds. It refers to a group or compound having two perfluorinated groups (e.g., a perfluoroalkylene and/or perfluoroalkyl) linked with an oxygen atom. That is, there is a single caternated oxygen atom. The perfluorinated groups can be saturated or unsaturated and can be linear, branched, cyclic, or a combination thereof.

The term “perfluoropolyether” refers to a polyether in which all of the C—H bonds are replaced with C—F bonds. It refers to a group or compound having three or more perfluorinated groups (e.g., a perfluoroalkylene and/or perfluoroalkyl) linked with oxygen atoms. That is, there are two or more caternated oxygen atoms. The perfluorinated groups can be saturated or unsaturated and can be linear, branched, cyclic, or a combination thereof.

The term “perfluoroalkyl” refers to an alkyl with all the hydrogen atoms replaced with fluorine atoms. Stated differently, all of the C—H bonds are replaced with C—F bonds.

The term “perfluoroalkane” refers to an alkane with all the C—H bonds replaced with C—F bonds.

The term “perfluoroalkylene” refers to an alkylene with all of the C—H bonds replaced with C—F bonds.

The term “perfluoroalkyleneoxy” refers to an alkyleneoxy group with all of the C—H bonds replaced with C—F bonds. Likewise, the term “poly(perfluoroalkyleneoxy)” refers to a divalent group that contains multiple perfluoralkyleneoxy groups.

The term “perfluoroalkoxy” refers to an alkoxy with all of the hydrogen atoms replaced with fluorine atoms. All of the C—H bonds are replaced with C—F bonds.

The term “quaternary nitrogen” refers to a tetravalent nitrogen atom bonded to four groups and that has a positive charge. The positively charged quaternary nitrogen group has associated with it a counter ion (anion).

The term “silyl” refers to a monovalent group of formula —Si(R_{c})₃ where R^{c} is hydroxyl, a hydrolyzable group, or a non-hydrolyzable group. In many embodiments, the silyl group is a “reactive silyl” group, which means that the silyl group contains at least one R^{c} group that is a hydroxyl group or hydrolyzable group. Some reactive silyl groups are of formula —Si(R²)₃₋ₓ(R³)ₓ where each group R² is independently hydroxyl or a hydrolyzable group and each group R³ is independently a non-hydrolyzable group. The variable x is an integer equal to 0, 1, or 2.

The term “hydrolyzable group” refers to a group that can react with water having a pH of 1 to 10 under conditions of atmospheric pressure. The hydrolyzable group is often converted to a hydroxyl group when it reacts. The hydroxyl group often undergoes further reactions. Typical hydrolyzable groups include, but are not limited to, alkoxy, aryloxy, aralkyloxy, acyloxy, or halo. As used herein, the term is often used in reference to one of more groups bonded to a silicon atom in a silyl group.

The term “non-hydrolyzable group” refers to a group that cannot react with water having a pH of 1 to 10 under conditions of atmospheric pressure. Typical non-hydrolyzable groups include, but are not limited to alkyl, aryl, and aralkyl. As used herein, the term is often used in reference to one of more groups bonded to a silicon atom in a silyl group.

The term “sulfinyl” means a divalent group of formula —SO—.

The term “sulfonyl” means a divalent group of formula —SO₂—.

The term “sulfonylimino” means a divalent group of formula —SO₂N(R^{a})—, wherein R^{a} is hydrogen, alkyl, aryl or aralkyl. Suitable alkyl R^{a} groups often have 1 to 10 carbon atoms, 1 to 6 carbon atoms, or 1 to 4 carbon atoms. Suitable aryl R^{a} groups often have 6 to 12 carbon atoms such as, for example, phenyl. Suitable aralkyl R^{a} groups often have an alkyl group with 1 to 10 carbon atoms, 1 to 6 carbon atoms, or 1 to 4 carbon atoms that is substituted with an aryl having 6 to 12 carbon atoms such as, for example, phenyl. The term sulfonylimino can be referred to interchangeably as an iminosulfonyl group. This term is sometimes referred to as a sulfonamido group.

The term “thio” means a divalent group of formula —S—.

The term “tertiary nitrogen” refers to a nitrogen atom that is bonded to three groups that are not equal to hydrogen. The tertiary nitrogen often functions as a branching point in a molecular chain and is usually bonded to three carbon atoms.

The terms “fluorinated layer” and “hydrophobic fluorinated layer” are used interchangeably and refer to a hydrophobic layer attached to the primer layer by reaction of a surface of the acid-sintered silica nanoparticles in the primer layer with a fluorinated silane compound having a reactive silyl group and a hydrophobic fluorinated group such as a hydrophobic perfluorinated group.

In a first aspect, an article is provided that includes (a) a substrate, (b) a primer layer attached to a surface of the substrate, and (c) a hydrophobic fluorinated layer attached to the primer layer. The primer layer is positioned between the substrate and the hydrophobic fluorinated layer. The primer layer contains a plurality of acid-sintered silica nanoparticles arranged to form a continuous three-dimensional porous network. The hydrophobic fluorinated layer contains the reaction product of a fluorinated silane with a surface of the acid-sintered silica nanoparticles in the primer layer. The fluorinated silane contains both a reactive silyl group and a fluorinated group.

The articles have a hydrophobic surface (i.e., coating) resulting from the combined use of a primer layer and a hydrophobic fluorinated layer. Providing such a coating that is durable (e.g., a coating that can withstand repeating rubbing and/or cleaning) has been a challenge in the art. By using a primer layer containing acid-sintered silica nanoparticles, a fluorinated layer can be indirectly attached to a variety of substrate materials. The primer layer contains multiple silica nanoparticles that are joined together into a three dimensional network by low temperature (e.g., at or near room temperature) sintering in the presence of an acid. The primer layer typically durably adheres to a variety of substrate surfaces. The fluorinated layer typically durably adheres to the primer layer and results from a chemical reaction between a fluorinated silane and the acid-sintered silica nanoparticles in the primer layer. That is, the fluorinated silane is covalently attached to the primer layer through a —Si—O—Si— group.

The use of the primer layer between the hydrophobic fluorinated layer and the substrate allows the use of many substrates that would not form durable coatings if the fluorinated silane were applied directly to the substrate. More specifically, substrates that do not have a hydroxyl group that can react with the fluorinated silane compound used to form the hydrophobic fluorinated layer can be used. This allows that use of a wider range of substrate surfaces than have typically been considered suitable for use with coating compositions based on fluorinated silanes (i.e., the substrates lack a group that can react with the silyl group of the fluorinated silanes).

Suitable substrates can be flexible or rigid, opaque or transparent, reflective or non-reflective, and of any desired size and shape. The substrate can have a surface that is a polymeric material, glass or ceramic material, metal, composite material (e.g., polymer material with inorganic materials), and the like. The substrates can be sheets, films, molded shapes, or other types of surfaces.

Suitable polymeric materials for substrates include, but are not limited to, polyesters (e.g., polyethylene terephthalate or polybutylene terephthalate), polycarbonates, acrylonitrile butadiene styrene (ABS) copolymers, poly(meth)acrylates (e.g., polymethylmethacrylate or copolymers of various (meth)acrylates), polystyrenes, polysulfones, polyether sulfones, epoxy polymers (e.g., homopolymers or epoxy addition polymers with polydiamines or polydithiols), polyolefins (e.g., polyethylene and copolymers thereof or polypropylene and copolymers thereof), polyvinyl chlorides, polyurethanes, fluorinated polymers, cellulosic materials, derivatives thereof, and the like. In some embodiments, where increased transmissivity is desired, the polymeric substrate can be transparent. The term “transparent” means transmitting at least 85 percent, at least 90 percent, or at least 95 percent of incident light in the visible spectrum (wavelengths in the range of 400 to 700 nanometers). Transparent substrates may be colored or colorless.

Suitable metals include, for example, pure metals, metal alloys, metal oxides, and other metal compounds. Examples of metals include, but are not limited to, chromium, iron, aluminum, silver, gold, copper, nickel, zinc, cobalt, tin, steel (e.g., stainless steel or carbon steel), brass, oxides thereof, alloys thereof, and mixtures thereof.

In some embodiments, the substrate is hydrophobic. The terms “hydrophobic” and “hydrophobicity” refer to a surface on which drops of water or aqueous solutions exhibit a static water contact angle of at least 50 degrees, at least 60 degrees, at least 70 degrees, at least 90 degrees, or at least 100 degrees. The primer layer and/or the fluorinated layer may further enhance the hydrophobicity of the substrate. In many embodiments, the hydrophobicity of the substrate is further enhanced by the primer layer and/or the hydrophobic fluorinated layer.

A primer layer is applied to the substrate surface. The primer layer includes a porous network of acid-sintered silica nanoparticles. The term “nanoparticle” refers to silica particles that are submicron in size. The nanoparticles typically have an average particle size, which typically refers to the average longest dimension of the particles, that is no greater than 500 nanometers, no greater than 200 nanometers, no greater than 100 nanometers, no greater than 75 nanometers, no greater than 50 nanometers, no greater than 40 nanometers, no greater than 25 nanometers, or no greater than 20 nanometers.

The average particle size is often determined using transmission electron microscopy but various light scattering methods can be used as well. The average particle size refers to the average particle size of the primary silica nanoparticles used to form the primer layer coating. The average particle size typically refers to the average size of non-agglomerated and/or non-aggregated and/or non-sintered single nanoparticles of silica. That is, the average particle size refers to the average particle size of the primary silica nanoparticles prior to sintering under acidic conditions.

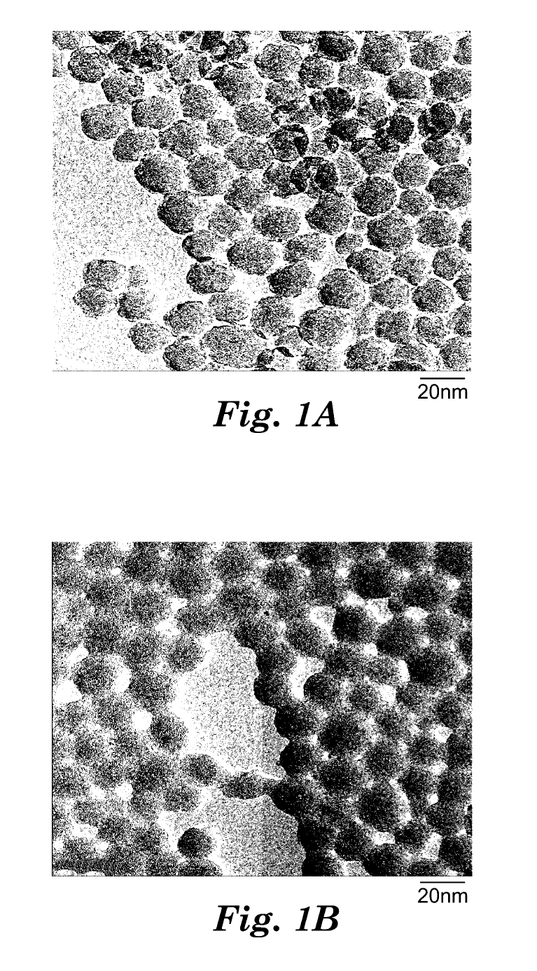

The silica nanoparticles in the primer layer are acid-sintered. At least some adjacent nanoparticles in the porous network tend to have bonds such as silica “necks” joining them together. These silica necks are typically formed by acidification of the silica nanoparticles. Stated differently, at least some adjacent silica nanoparticles tend to be joined together forming a three dimensional porous network. FIG. 1B is a transmission electron micrograph of one example primer layer. Unlike fumed silica particles that are simply chains of sintered silica nanoparticles, the acid-sintered primer layer is a continuous network of sintered nanoparticles that can be arranged to form a layer. The chains of fumed silica are not connected together and can only be used to form a layer by combination with a binder such as a polymeric binder. In contrast, the primer layer of the acid-sintered silica nanoparticles typically does not include an organic binder. Further, fumed silica particles are formed at relatively high temperatures such as at temperatures greater than 300° C., greater than 400° C., or greater then 500° C. In contrast, the acid-sintered primer layer is formed by sintering the silica nanoparticles at relatively low temperatures such as at or near room temperature in the presence of an acid.

The term “porous” refers to the presence of voids between the individual silica nanoparticles within the continuous primer layer coating. Preferably, when dried, the network has a porosity of 20 to 50 volume percent, 25 to 45 volume percent, or 30 to 40 volume percent. In some embodiments the porosity may be higher. Porosity may be calculated from the refractive index of the coating according to published procedures such as in W. L. Bragg, A. B. Pippard, Acta Crystallographica, volume 6, page 865 (1953). Porosity tends to correlate to the roughness of the surface. Unexpectedly, the porosity tends to also correlate with the hydrophobicity of the surface. That is, increased surface roughness tends to lead to increased hydrophobicity. Porosity of the surface can often be increased by using silica nanoparticles with a larger average particle size or by using a mixture of silica nanoparticles with different shapes.

The term “network” refers to a continuous three-dimensional structure formed by linking together silica nanoparticles. The term “continuous” means that the individual silica nanoparticles are linked over the dimension of the primer layer coating. The primer layer typically has virtually no discontinuities or gaps in the areas where the primer layer coating composition is applied to the substrate.

The primary silica nanoparticles used to prepare the primer layer coating compositions can have any desired shape or mixture of shapes. The silica nanoparticles can be spherical or non-spherical (i.e., acicular) with any desired aspect ratio. Aspect ratio refers to the ratio of the average longest dimension of the nanoparticles to the average shortest dimension of acicular silica nanoparticles. The aspect ratio of acicular silica nanoparticles is often at least 2:1, at least 3:1, at least 5:1, or at least 10:1. Some acicular nanoparticles are in the shape of rods, ellipsoids, needles, and the like. The shape of the nanoparticles can be regular or irregular. The porosity of the coatings can be varied by changing the amount of regular and irregular shaped nanoparticles in the composition and/or by changing the amount of spherical and acicular nanoparticles in the composition.

If the silica nanoparticles are spherical, the average diameter is often less than 50 nanometers, less than 40 nanometers, less than 25 nanometers, or less than 20 nanometers. Some nanoparticles can have an even smaller average diameter such as less than 10 nanometers or less than 5 nanometers.

If the silica nanoparticles are acicular, they often have an average width (smallest dimension) equal to at least 1 nanometer, at least 2 nanometers, or at least 5 nanometers. The average width of acicular silica nanoparticles is often no greater than 25 nanometers, no greater than 20 nanometers, or no greater than 10 nanometers. The acicular silica nanoparticles can have an average length D₁ measured by dynamic light scattering methods that is, for example, at least 40 nanometers, at least 50 nanometers, at least 75 nanometers, or at least 100 nanometers. The average length D₁ (e.g., longer dimension) can be up to 200 nanometers, up to 400 nanometers, or up to 500 nanometers. The acicular colloidal silica particles may have degree of elongation D₁/D₂ in a range of 5 to 30, wherein D₂ means a diameter in nanometers calculated by the equation D₂=2720/S and S means specific surface area in meters squared per gram (m²/gram) of the nanoparticle, as described in U.S. Pat. No. 5,221,497 (Watanabe et al.).

In many embodiments, the silica nanoparticles are selected to have an average specific surface area equal to at least 150 m²/gram, at least 200 m²/gram, at least 250 m²/gram, at least 300 m²/gram, or at least 400 m²/gram. Spherical nanoparticles having average specific surface areas equal to at least 150 m²/gram often have an average diameter less than 40 nanometers, less than 30 nanometers, less than 25 nanometers, or less than 20 nanometers.

In certain embodiments, the silica nanoparticles preferably have an average particle size (i.e., longest dimension) that is no greater than 50 nanometers, no greater than 40 nanometers, or no greater than 25 nanometers. If desired, larger silica nanoparticles may be added in limited amounts that do not deleteriously decrease the coatability of the primer layer coating composition on a selected substrate, that do not reduce the desired transmissivity of the resulting primer layer coating, and/or that do not reduce the desired hydrophobicity of the resulting primer layer coating. Thus, various sizes and/or various shapes of particles may be used in combination.

In certain embodiments, bimodal distributions of particle sizes may be used. For example, nanoparticles having an average particle size of at least 50 nanometers (e.g., in the range of 50 to 200 nanometers or in the range of 50 to 100 nanometers) can be used in combination with nanoparticles having an average diameter no greater than 40 nanometers. The weight ratio of the larger to smaller nanoparticles can be in the range of 2:98 to 98:2, in the range of 5:95 to 95:5, in the range of 10:90 to 90:10, or in the range of 20:80 to 80:20.

Generally, the total weight of silica nanoparticles (regardless of size) in a primer layer coating composition is at least 0.1 weight percent based on the total weight of the primer layer coating composition. For example, the primer layer coating composition can include at least 1 weight percent, at least 2 weight percent, or at least 5 weight percent silica nanoparticles. The primer layer coating composition often contains up to 40 weight percent, up to 30 weight percent, up to 25 weight percent up to 20 weight percent, or up to 10 weight percent silica nanoparticles. The amount of silica nanoparticles in the primer layer coating composition can be, for example, in the range of 0.1 to 40 weight percent, in the range of 1 to 40 weight percent, in the range of 1 to 25 weight percent, in the range of 1 to 20 weight percent, in the range of 5 to 20 weight percent, in the range of 1 to 10 weight percent, in the range of 5 to 10 weight percent, or in the range of 1 to 7 weight percent. In some example primer layer coating compositions, a mixture of nanoparticles of different sizes can be used. For example, the primer layer coating compositions can include 0.1 to 20 weight percent silica nanoparticles having an average particle size of 40 nanometers or less and 0 to 20 weight percent silica nanoparticles having an average particle size of 50 nanometers or greater. The amount is based on a total weight of the primer layer coating composition.

The silica nanoparticles are typically commercially available in the form of a silica sol. Some example spherical silica nanoparticles are available in the form of aqueous-based silica sols such as those commercially available under the trade designation LUDOX (e.g., LUDOX SM) from E.I. DuPont de Nemours and Co., Inc. (Wilmington, Del.). Other example aqueous-based silica sols are commercially available under the trade designation NYACOL from Nyacol Co. (Ashland, Mass.). Still other example aqueous-based silica sols are commercially available under the trade designation NALCO (e.g., NALCO 1115, NALCO 2326, and NALCO 1130) from Ondea Nalco Chemical Co. (Oak Brook, Ill.). Yet other example aqueous-based silica sols are commercially available under the trade designation REMASOL (e.g., REMASOL SP30) from Remet Corporation (Utica, N.Y.) and under the trade designation SILCO (e.g., SILCO LI-518) from Silco International (Portland, Oreg.).

Suitable non-spherical (i.e., acicular) silica nanoparticles may be obtained in the form of aqueous-based silica sols under the trade designation SNOWTEX from Nissan Chemical Industries (Tokyo, Japan). For example, SNOWTEX-UP contains silica nanoparticles having a diameter in the range of about 9 to 15 nanometers with lengths in a range of 40 to 300 nanometers. SNOWTEX-PS-S and SNOWTEX-PS-M have a chain of beads morphology. The SNOWTEX-PS-M particles are about 18 to 25 nanometers in diameter and have lengths of 80 to 150 nanometers. The SNOWTEX-PS-S has a particle diameter of 10-15 nm and a length of 80-120 nanometers.

Either water or a water-miscible organic solvent can be used to dilute commercially available aqueous-based silica sols. However, sols of sodium stabilized silica nanoparticles are usually acidified prior to dilution with water or a water-miscible organic solvent such as ethanol Dilution prior to acidification may yield poor or non-uniform primer layer coatings. Ammonium stabilized silica nanoparticles may generally be diluted and acidified in any order.

The primer layer coating composition contains an acid having a pKa (H₂O) that is less than or equal to 3.5. The use of weaker acids such as those having a pKa greater than 4 (e.g., acetic acid) typically does not result a uniform coating having the desirable transmissivity and/or durability. In particular, coating compositions with weaker acids such as acetic acid typically bead up on the surface of a substrate. The pKa of the acid added to the coating composition is often less than 3, less than 2.5, less than 2, less than 1.5, or less than 1 Useful acids that can be used to adjust the pH of the primer layer coating composition include both organic and inorganic acids. Example acids include, but are not limited to, oxalic acid, citric acid, H₂SO₃, H₃PO₄, CF₃CO₂H, HCl, HBr, HI, HBrO₃, HNO₃, HClO₄, H₂SO₄, CH₃SO₃H, CF₃SO₃H, CF₃CO₂H, and CH₃SO₂OH. In many embodiments, the acid is HCl, HNO₃, H₂SO₄, or H₃PO₄. In some embodiments, it is desirable to provide a mixture of an organic and inorganic acid. If commercially available acidic silica sols are used, the addition of one of the acids listed above typically result in primer layers having the desired uniformity.

The coating composition generally contains sufficient acid to provide a pH no greater than 5 The pH is often no greater than 4.5, no greater than 4, no greater than 3.5, or no greater than 3. For example, the pH is often in the range of 2 to 5. In some embodiments, the coating composition can be adjusted to a pH in the range of 5 to 6 after first reducing the pH to less than 5 This pH adjustment can allow the coating of pH sensitive substrates.

The primer layer coating composition containing the acidified silica nanoparticles usually is applied to a substrate surface and then dried. In many embodiments, the primer layer coating composition contains (a) silica nanoparticles having an average particle diameter (i.e., average particle diameter prior to acid-sintering) no greater than 40 nanometers and (b) an acid with a pKa (H₂O) that is less than or equal to 3.5. The pH of the primer layer coating composition is pH is less than or equal to 5 such as in the pH range of 2 to 5.

The acidified silica nanoparticles appear to be stable when the pH is in the range 2 to 4. Light-scattering measurements have demonstrated that the acidified silica nanoparticles at pH in the range of 2 to 3 and at a concentration of 10 weight percent silica nanoparticles can retain the same size for more than a week or even more than a month. Such acidified primer layer coating compositions are expected to remain stable even longer if the concentration of silica nanoparticles is lower than 10 weight percent.

The primer layer coating composition typically further includes water or a mixture of water plus a water-miscible organic solvent. Suitable water-miscible organic solvents include, but are not limited to, various alcohols (e g, ethanol or isopropanol) and glycols (e.g., propylene glycol), ethers (e.g., propylene glycol methyl ether), ketones (e.g., acetone), and esters (e.g., propylene glycol monomethyl ether acetate). The silica nanoparticles included in the primer layer coating compositions typically are not surface modified.

In some embodiments, optional silane coupling agents, which contain a plurality of reactive silyl groups, can be added to the primer layer coating compositions. Some example coupling agents include, but are not limited to, tetraalkoxysilanes (e.g., tetraethylorthosilicate (TEOS)) and oligomeric forms of tetraalkoxysilane such as alkyl polysilicates (e.g., poly(diethoxysiloxane). These coupling agents may, at least in some embodiments, improve binding between silica nanoparticles. If added, the coupling agent is typically added to the primer layer coating composition at levels of 0.1 to 30 weight percent based on the weight of the silica nanoparticles in the coating composition. In some examples, the coupling agent is present in an amount in the range of 0.1 to 25 weight percent, in the range of 1 to 25 weight percent, in the range of 5 to 25 weight percent, in the range of 10 to 25 weight percent, in the range of 0.1 to 20 weight percent, in the range of 1 to 20 weight percent, in the range of 1 to 15 weight percent, in the range of 1 to 10 weight percent, or in the range of 1 to 5 weight percent based on the weight of silica nanoparticles. In other examples, however, the primer layer coating compositions do not include a coupling agent.

Many primer layer coating compositions do not contain other types of binders other than coupling agents. That is, many primer layer coating compositions do not contain typical polymeric binders.

The primer layer coating compositions can be applied directly to any substrate. The substrate can be an organic material (e.g., polymeric) or inorganic material (e.g., glass, ceramic, or metal). In many embodiments, the substrate is hydrophobic. The wetting property of the primer layer coating compositions on hydrophobic surfaces (e.g., hydrophobic polymeric substrates such as polyethylene terephthalate (PET) or polycarbonate (PC)) is a function of the pH of the primer layer coating compositions and the pKa of the acid used to adjust the pH. The coating compositions can be applied, for example, to hydrophobic substrates when acidified to a pH in the range of 2 to 5. In contrast, similar primer layer coating compositions with a neutral or basic pH tend to bead up on the hydrophobic substrates.

The primer layer is a continuous network of acid-sintered silica nanoparticles. As applied to the substrate surface, the primer layer coating composition is a sol. After the primer layer coating composition is applied to the substrate, a gelled material forms as the sol dries and the silica nanoparticles sinter to form the continuous network. Micrographs reveal the formation of silica “necks” between adjacent nanoparticles that are created by the acid even in the absence of other silicon-containing materials such as the silane coupling agents. The formation of these necks is attributed to the catalytic action of strong acid in making and breaking siloxane bonds.

To uniformly apply a primer layer coating composition onto a substrate such as a hydrophobic substrate, it optionally may be desirable to increase the surface energy of the substrate surface and/or reduce the surface tension of the primer layer coating composition. The surface energy of the substrate surface may be increased by oxidizing the substrate surface prior to coating using methods such as corona discharge or flame treatment methods. These methods may also improve adhesion of the primer layer coating composition to the substrate. Other methods capable of increasing the surface energy of the substrate include the use of additional primer layers such as thin coatings of polyvinylidene chloride (PVDC). Alternatively, the surface tension of the primer layer coating composition may be decreased by addition of lower alcohols (e.g., alcohols having 1 to 8 carbon atoms, 1 to 6 carbon atoms, or 1 to 4 carbon atoms).

In some instances, however, in order to improve the coating hydrophobicity for desired properties and to ensure uniform coating of the article from an aqueous or aqueous-based medium (e.g., a water/alcohol medium), it may be beneficial to add a wetting agent, which is typically a surfactant, to the primer layer coating composition. Surfactants are molecules having both hydrophilic (polar) and hydrophobic (non-polar) regions and that are capable of reducing the surface tension of the primer layer coating composition. Useful surfactants may include those disclosed, for example, in U.S. Pat. No. 6,040,053 (Scholz et al.). If added, the surfactant is typically present in an amount up to 5 weight percent based on a total weight of the primer layer coating composition. For example, the amount can be up to 4 weight percent, up to 2 weight percent, or up to 1 weight percent. The surfactant is typically present in an amount equal to at least 0.001 weight percent, at least 0.005 weight percent, at least 0.01 weight percent, at least 0.05 weight percent, at least 0.1 weight percent or at least 0.5 weight percent.

Some surfactants for use in the primer layer coating compositions are anionic surfactants. Useful anionic surfactants often have a molecular structure with (1) at least one hydrophobic group such as a C₆-C₂₀ alkyl, alkylaryl, and/or alkenyl groups, (2) at least one anionic group such as sulfate, sulfonate, phosphate, polyoxyethylene sulfate, polyoxyethylene sulfonate, polyoxyethylene phosphate, and the like, and/or the salts of such anionic groups. Suitable salts include alkali metal salts, ammonium salts, tertiary amino salts, and the like. Representative commercial examples of useful anionic surfactants include, but are not limited to, sodium lauryl sulfate (available, for example, under the trade designation TEXAPON L-100 from Henkel Inc. (Wilmington, Del.) and under the trade designation POLYSTEP B-3 from Stepan Chemical Co. (Northfield, Ill.)); sodium lauryl ether sulfate (available, for example, under the trade designation POLYSTEP B-12 from Stepan Chemical Co. (Northfield, Ill.)); ammonium lauryl sulfate (available, for example, under the trade designation STANDAPOL A from Henkel Inc. (Wilmington, Del.)); and sodium dodecyl benzene sulfonate (available, for example, under the trade designation SIPONATE DS-10 from Rhone-Poulenc, Inc. (Cranberry, N.J.)).

Other useful surfactants for use in the primer layer coating compositions are non-ionic surfactants. Suitable non-ionic surfactants include, but are not limited to, polyethoxylated alkyl alcohols (available, for example, under the trade designations BRIJ 30 and BRIJ 35 from ICI Americas, Inc. (Wilmington, Del.) and under the trade designation TERGITOL TMN-6 from Dow Chemical (Midland, Mich.)); polyethoxylated alkyl phenols (available, for example, under the trade designations TRITON X-100 from Roche (Mannheim, Germany) and ICONOL NP-70 from BASF Corp. (Florham Park, N.J.)); and polyethylene glycol/polypropylene glycol block copolymers (available, for example, under the trade designations TETRONIC 1502, TETRONIC 908, and PLURONIC F38 from BASF Corp. (Florham Park, N.J.)).

The primer layer coating compositions are typically applied to the surface of the substrate using conventional techniques such as, for example, bar coating, roll coating, curtain coating, rotogravure coating, knife coating, spray coating, spin coating, or dip coating techniques. Coating techniques such as bar coating, roll coating, and knife coating are often used to adjust the thickness of the primer layer coating composition. The primer layer coating compositions can be coated on one or more sides of the substrate.

The optimal average dry coating thickness of the primer layer is dependent upon the particular primer layer coating composition used. In general, average thickness of the dry primer layer coating is in the range of 100 to 10,000 angstroms (Å), in the range of 500 to 2500 Å, in the range of 750 to 2000 Å, or in the range of 1000 to 1500 Å. The thickness can be measured using an ellipsometer such as a Gaertner Scientific Corp. Model No. L115C. Although the actual coating thickness can vary considerably from one particular point to another, it is often desirable to apply the primer layer coating composition uniformly over the surface of the substrate. For example, to minimize visible interference color variations in the coating, it may be desirable to control the average coating thickness within 200 Å, within 150 Å, or within 100 Åacross the substrate.

Once applied to the substrate, the coated primer layer coating composition is typically dried at temperatures in a range from 20° C. to 150° C. An oven with circulating air or inert gas such as nitrogen is often used for drying purposes. The temperature may be increased further to speed the drying process, but care should be exercised to avoid damage to the substrate. For inorganic substrates, the drying temperature can be above 200° C.

As used herein, the “dried primer layer” refers to the primer layer remaining after the drying process. The dried primer layer can contain some water such as the amount of water typically associated with equilibrium of the primer layer with the atmospheric moisture present in the environment of the primer layer. This equilibrium amount of water is typically no greater than 5 weight percent, not greater than 3 weight percent, no greater than 2 weight percent, no greater than 1 weight percent, or not greater than 0.5 weight percent based on a total weight of the dried primer layer.

The primer layer typically contains at least 60 weight percent, at least 65 weight percent, at least 70 weight percent, at least 75 weight percent, at least 80 weight percent, at least 85 weight percent silica nanoparticles based on a total weight of the dried primer layer. The dried primer layer can contain up to 90 weight percent, up to 95 weight percent, or up to 99 percent or higher silica nanoparticles based on the total weight of the dried primer layer. For example, the dried primer layer can contain 60 to greater than 99 weight percent, 60 to 95 weight percent, 60 to 90 weight percent, 70 to 99 weight percent, 70 to 95 weight percent, 75 to 99 weight percent, 85 to 99 percent, 85 to 95 weight percent, 80 to 99 weight percent, or 85 to 95 weight percent silica nanoparticles.

For some uses, it may be desirable to maximize light transmission (i.e., minimize or eliminate reflection) and minimize reflection by the substrate. Stated differently, the primer layer can function as an anti-reflective layer. This can be accomplished by matching the refractive index of the primer layer as closely as possible with the square root of the refractive index of the substrate and by providing a primer layer thickness equal to one-fourth (¼) of the optical wavelength of the incident light. The voids in the coating provide a multiplicity of sub-wavelength interstices between the silica nanoparticles where the refractive index (RI) abruptly changes from that of air (RI equal to 1) to that of the silica nanoparticles (RI is equal to 1.44). By adjusting the porosity, the refractive index of the primer layer can be adjusted as discussed in U.S. Pat. No. 4,816,333 (Lange, et al.). If desired, the porosity can be adjusted to provide a primer layer having a refractive index very close to the square root of the refractive index of the substrate.

Dried primer layer coatings with porosity in the range of 25 to 45 volume percent or in the range of 30 to 40 volume percent often have a refractive index in the range of 1.2 to 1.4 or in the range of 1.25 to 1.36. If the refractive index is in one of these ranges, it tends to be approximately equal to the square root of the refractive indices of a polyester, polycarbonate, or poly(methyl methacrylate) substrate. For example, a primer layer coating having a refractive index of 1.25 to 1.36 is capable of providing an anti-reflective surface when coated on a polyethylene terephthalate substrate (RI equal to 1.64) at a thickness of 1000 to 2000 Å. If anti-reflection is not a needed characteristic of the coating, any desired thickness can be used. For example, the primer layer can have a thickness up to a few micrometers or mils (i.e., 1 mil is equal to 0.001 inches). The mechanical properties of the primer layer often improve as the thickness is increased.

In addition to the substrate and the primer layer, the articles contain a hydrophobic fluorinated layer that is attached to primer layer. More particularly, the hydrophobic fluorinated layer contains the reaction product of a fluorinated silane with a surface of the acid-sintered silica nanoparticles in the primer layer. The fluorinated silane contains both a reactive silyl group and a hydrophobic fluorinated group such as a hydrophobic perfluorinated group. The reactive silyl group has at least one hydroxyl group or hydrolyzable group that can react with the acid-sintered silica nanoparticles.

In many embodiments, the fluorinated silane used to form the fluorinated layer of the article is of Formula (I).

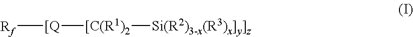

In Formula (I), group R_{f} is a z-valent radical of a perfluoroether, perfluoropolyether, or perfluoroalkane (i.e., R_{f} is (a) a monovalent or divalent radical of a perfluoroether, (b) a monovalent or divalent radical of a perfluoropolyether, or (c) a monovalent or divalent radical of a perfluoroalkane). Group Q is a single bond, a divalent linking group, or trivalent linking group. Each group R¹ is independently hydrogen or alkyl. Each group R² is independently hydroxyl or a hydrolyzable group. Each group R³ is independently a non-hydrolyzable group. The variable x is an integer equal to 0, 1, or 2. The variable y is an integer equal to 1 or 2. The variable z is an integer equal to 1 or 2.

Group R_{f} is a z-valent radical of a polyether, a z-valent radical of a perfluoropolyether, or a z-valent radical of a perfluoroalkane. As used herein, the term “z-valent radical” refers to a radical having a valence equal to the variable z. Because z is in integer equal to 1 or 2, a z-valent radical is a monovalent or divalent radical. Thus, R_{f} is (a) a monovalent or divalent radical of a perfluoroether, (b) a monovalent or divalent radical of a perfluoropolyether, or (c) a monovalent or divalent radical of a perfluoroalkane.

If the variable z in Formula (I) is equal to 1, the fluorinated silane is of Formula (Ia) where group R_{f} is a monovalent group.

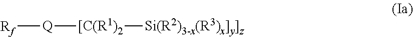

Such a compound can be referred to as a monopodal fluorinated silane because there is a single end group of formula -Q-[C(R¹)₂—Si(R²)₃₋ₓ(R³)ₓ]_{y}. There can be a single silyl group if the variable y is equal to 1 or two silyl groups if the variable y is equal to 2.

If the variable z in Formula (I) is equal to 2, the fluorinated silane is of Formula (Ib) where group R_{f} is a divalent group.

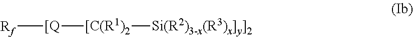

Such a compound can be referred to as a bipodal fluorinated silane because there are two end groups of formula -Q-[C(R¹)—Si(R²)₃₋ₓ(R³)ₓ]_{y}. Each end group can have a single silyl group if the variable y is equal to 1 or two silyl groups if the variable y is equal to 2. Formula (Ib) can be written as the following equivalent formula that emphasizes the divalent nature of the R_{f} group.

[(R³)ₓ(R²)₃₋ₓSi—C(R¹)₂]_{y}-Q-R_{f}-Q-[C(R¹)₂—Si(R²)₃₋ₓ(R³)ₓ]_{y}

Any suitable perfluorinated group can be used for R_{f}. The perfluorinated group is typically a monovalent or divalent radical of a perfluoroether, perfluoropolyether, or perfluoroalkane. This group can have a single carbon atoms but often has at least 2 carbon atoms, at least 4 carbon atoms, at least 6 carbon atoms, at least 8 carbon atoms, or at least 12 carbon atoms. The R_{f} group often has up to 300 or more carbon atoms, up to 200 carbon atoms, up to 100 carbon atoms, up to 80 carbon atoms, up to 60 carbon atoms, up to 50 carbon atoms, up to 40 carbon atoms, up to 20 carbon atoms, or up to 10 carbon atoms. The R_{f} group is usually saturated and can be linear, branched, cyclic (e.g., alicyclic), or a combination thereof.

R_{f} groups that are monovalent or divalent radicals of a perfluoroether or perfluoropolyether often contains at least one perfluorinated unit selected from —C_{b}F_{2b}O—, —CF(Z)O—, —CF(Z)C_{b}F_{2b}O—, —C_{b}F_{2b}CF(Z)O—, —CF₂CF(Z)O—, or combinations thereof. The variable b is an integer equal to at least 1. For example, the variable b can be an integer in the range of 1 to 10, in the range of 1 to 8, in the range of 1 to 4, or in the range of 1 to 3. The group Z is a perfluoroalkyl, perfluoroalkoxy, perfluoroether, or perfluoropolyether group. Any of these Z groups can be linear, branched, cyclic, or a combination thereof. Example perfluoroalkyl, perfluoralkoxy, perfluoroether, and perfluoropolyether Z groups often have up to 20 carbon atoms, up to 16 carbon atoms, up to 12 carbon atoms, up to 8 carbon atoms, or up to 4 carbon atoms. Perfluoropolyether groups for Z can have, for example, up to 10 oxygen atoms, up to 8 oxygen atoms, up to 6 oxygen atoms, up to 4 oxygen atoms, or up to 3 oxygen atoms. In some embodiments, Z is a —CF₃ group.

Monovalent perfluoroether groups are of general formula R_{f}¹—O—R_{f}²— where R_{f}¹ is a perfluoroalkyl and R_{f}² is a perfluoroalkylene. R_{f}¹ and R_{f}² each independently have at least 1 carbon atoms and often have at least 2 carbon atoms, at least 3 carbon atoms, or at least 4 carbon atoms. Groups R_{f}¹ and R_{f}² each independently can have up to 50 carbon atoms, up to 40 carbon atoms, up to 30 carbon atoms, up to 25 carbon atoms, up to 20 carbon atoms, up to 16 carbon atoms, up to 12 carbon atoms, up to 10 carbon atoms, up to 8 carbon atoms, up to 4 carbon atoms, or up to 3 carbon atoms. In many embodiments, the perfluoroalkylene groups and/or the perfluoroalkyl groups have 1 to 10 carbon atoms, 1 to 8 carbon atoms, 1 to 6 carbon atoms, 1 to 4 carbon atoms, or 1 to 3 carbon atoms.

Monovalent perfluoroether groups often have a terminal group (i.e., R_{f}¹—O— group) of formula C_{b}F_{2b+1}O—, CF₂(Z¹)O—, CF₂(Z¹)C_{b}F_{2b}O—, C_{b}F_{2b+1}CF(Z¹)O—, or CF₃CF(Z¹)O— where b is the same as defined above. The group Z¹ is a perfluoroalkyl having up to 20 carbon atoms, up to 16 carbon atoms, up to 12 carbon atoms, up to 8 carbon atoms, up to 6 carbon atoms, or up to 4 carbon atoms. In some embodiments, Z¹ is a —CF₃ group. The terminal group is directly bonded to a perfluoroalkylene group. The perfluoroalkylene group can be linear or branched and often has up to 20 carbon atoms, up to 16 carbon atoms, up to 12 carbon atoms, up to 8 carbon atoms, or up to 4 carbon atoms. Specific examples of perfluoroether groups include, but are not limited to, CF₃CF₂OCF₂CF₂CF₂—, CF₃OCF₂CF₂CF₂—, C₃F₇OCF₂CF₂CF₂—, CF₃CF₂OCF(CF₃)CF₂—, CF₃OCF(CF₃)CF₂—, and C₃F₇OCF(CF₃)CF₂—.

Divalent perfluoroether groups are of general formula —R_{f}²—O—R_{f}³— where R_{f}² and R_{f}³ are each independently a perfluoroalkylene. Each perfluoroalkylene independently has at least 1 carbon atom, at least 2 carbon atoms, at least 3 carbon atoms, or at least 4 carbon atoms. Groups R_{f}² and R_{f}³ each independently can have up to 50 carbon atoms, up to 40 carbon atoms, up to 30 carbon atoms, up to 25 carbon atoms, up to 20 carbon atoms, up to 16 carbon atoms, up to 12 carbon atoms, up to 10 carbon atoms, up to 8 carbon atoms, up to 4 carbon atoms, or up to 3 carbon atoms. In many embodiments, each perfluoroalkylene group has 1 to 10 carbon atoms, 1 to 8 carbon atoms, 1 to 6 carbon atoms, 1 to 4 carbon atoms, 1 to 3 carbon atoms, or 1 to 2 carbon atoms.

Monovalent perfluoropolyether groups are of general formula R_{f}¹—O—(R_{f}²—O)ₐ—R_{f}³— where R_{f}¹ is a perfluoroalkyl, R_{f}² and R_{f}³ are each independently a perfluoroalkylene, and the variable a is an integer equal to at least 1. Groups R_{f}¹, R_{f}², and R_{f}³ are the same as defined above for perfluoroether groups. The variable a is any integer in the range of 1 to 50, in the range of 1 to 40, in the range of 1 to 30, in the range of 1 to 25, in the range of 1 to 20, or in the range of 1 to 10.

Monovalent perfluoropolyether groups often have a terminal group (i.e., R_{f}¹—O— group) of formula C_{b}F_{2b+1}O—, CF₂(Z)O—, CF₂(Z)C_{b}F_{2b}O—, C_{b}F_{2b+1}CF(Z)O—, or CF₃CF(Z)O— where b and Z are the same as defined above. The terminal group is directly bonded to at least one perfluoroalkyleneoxy or poly(perfluoroalkyleneoxy) group (i.e., —(R_{f}²—O)ₐ— group). Each perfluoroalkyleneoxy group often has 1 to 10 carbon atoms, 1 to 8 carbon atoms, 1 to 6 carbon atoms, 1 to 4 carbon atoms, or 1 to 3 carbon atoms. The perfluoroalkyleneoxy or poly(perfluoroalkyleneoxy) group is directly bonded to a perfluoroalkylene group (i.e., —R_{f}³—).

Representative examples of useful monovalent perfluoropolyether groups or terminal groups of monovalent perfluoropolyether groups include, but are not limited to, C₃F₇O(CF(CF₃)CF₂O)ₙCF(CF₃)—, C₃F₇O(CF(CF₃)CF₂O)ₙCF₂CF₂—, C₃F₇O(CF₂CF₂CF₂O)ₙCF₂CF₂—, C₃F₇O(CF₂CF₂CF₂O)ₙCF(CF₃)—, CF₃O(C₂F₄O)ₙCF₂—, CF₃O(CF₂O)ₘC₂F₄O)_{q}CF₂—, F(CF₂)₃O(C₃F₆O)ₙ(CF₂)₃—, and CF₃O(CF₂CF(CF₃)O)ₙ(CF₂O)X—. The group X is usually —CF₂—, —C₂F₄—, —C₃F₆—, or —C₄F₈—. The variable n is an integer that is often in the range of 1 to 50, in the range of 1 to 40, in the range of 1 to 30, in the range of 3 to 30, in the range of 1 to 20, in the range of 3 to 20, in the range of 1 to 10, or in the range of 3 to 10. Provided that the sum (m+q) is equal to at least one, the variables m and q can each independently be in the range of 0 to 50, in the range of 0 to 40, in the range of in the range of 0 to 30, in the range of 1 to 30, in the range of 3 to 20, or in the range of 3 to 10. The sum (m+q) is often in the range of 1 to 50, in the range of 1 to 40, in the range of 1 to 30, in the range of 3 to 20, in the range of 1 to 20, in the range of 3 to 20, in the range of 1 to 10, or in the range of 3 to 10.

Representative examples of divalent perfluoropolyether groups or segments include, but are not limited to, —CF₂O(CF₂O)ₘ(C₂F₄O)_{q}CF₂—, —CF₂O(C₂F₄O)ₙCF₂—, —(CF₂)₃O(C₄F₈O)ₙ(CF₂)₃—, —CF(CF₃)O(CF₂CF₂CF₂O)ₙCF₂CF₂—, —CF(CF₃)O(CF₂CF₂CF₂O)ₙCF(CF₃)—, —(CF₂)₃O(C₃F₆O)ₙ(CF₂)₃— and —CF(CF₃)(OCF₂CF(CF₃))ₘOCₜF₂ₜO(CF(CF₃)CF₂O)_{q}CF(CF₃)—. The variables n, m, and q are the same as defined above. The variable t is an integer in the range of 2 to 8, in the range of 2 to 6, in the range of 2 to 4, or in the range of 3 to 4.

In many embodiments, the perfluoropolyether (whether monovalent or divalent) includes at least one divalent hexafluoropropyleneoxy group (—CF(CF₃)—CF₂O— or —CF₂CF₂CF₂O—). Segments with —CF(CF₃)—CF₂O— can be obtained through the oligomerization of hexafluoropropylene oxide and can be preferred because of their relatively benign environmental properties. Segments with —CF₂CF₂CF₂O— can be obtained by anionic oligomerization of tetrafluorooxetane followed by direct fluorination. Example hexafluoropropyleneoxy groups include, but are not limited to, C₃F₇O(CF(CF₃)CF₂O)ₙCF(CF₃)—, C₃F₇O(CF(CF₃)CF₂O)ₙCF₂CF₂—, C₃F₇O(CF₂CF₂CF₂O)ₙCF₂CF₂—, C₃F₇O(CF₂CF₂CF₂O)ₙCF(CF₃)—, —CF(CF₃)O(CF(CF₃)CF₂O)ₙCF(CF₃)—, —CF(CF₃)O(CF(CF₃)CF₂O)ₙCF₂CF₂—, —CF(CF₃)O(CF₂CF₂CF₂O)ₙCF₂CF₂—, —CF(CF₃)O(CF₂CF₂CF₂O)ₙCF(CF₃)—, and —CF(CF₃)(OCF₂CF(CF₃))ₘOCₜF₂ₜO(CF(CF₃)CF₂O)_{q}CF(CF₃)—. The variables n, m, q, and t are the same as defined above.

Frequently, the compounds of Formula (I) are present as a mixture of materials having R_{f} groups of the same basic structure but with a different number of carbon atoms. For example, the compounds of Formula (I) can be a mixture of materials having different variables m, n, and/or q in the above example monovalent and divalent perfluoropolyether groups. As such, the number of repeating groups is often reported as an average number that may not be an integer.

The group Q in Formula (I) is a single covalent bond, a divalent linking group, or a trivalent linking group. If Q is a single bond, the variable y is equal to 1. For compounds of Formula (Ia) with a monovalent R_{f} group, if Q is a single covalent bond and y is equal to 1, the compounds are of Formula (Ia-1).

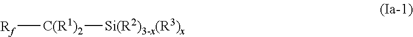

Similarly, for compounds of Formula (Ib) with a divalent R_{f} group, if Q is a single covalent bond and y is equal to 1, the compounds are of Formula (Ib-1).

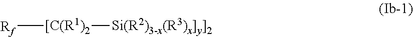

If the group Q is a divalent linking group, the variable y is equal to 1. For compounds of Formula (Ia) with a monovalent R_{f} group, if Q is a divalent group and y is equal to 1, the compounds are of Formula (Ia-2).

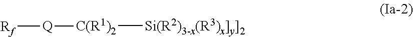

Similarly, for compounds of Formula (Ib) with a divalent R_{f} group, if Q is a divalent group and y is equal to 1, the compounds are of Formula (Ib-2).

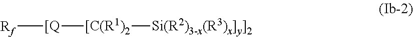

If the group Q is a trivalent linking group, the variable y is usually equal to 2. For compounds of Formula (Ia) with a monovalent R_{f} group, if Q is a trivalent group and y is equal to 2, the compounds are of Formula (Ia-3). There are two groups of formula —C(R¹)₂—Si(R²)₃₋ₓ(R³)ₓ.

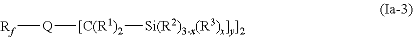

Similarly, for compounds of Formula (Ib) with a divalent R_{f} group, if Q is a trivalent group and y is equal to 2, the compounds are of Formula (Ib-3).

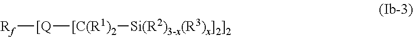

Group Q typically includes at least one alkylene group (e.g., an alkylene having 1 to 30 cabon atoms, 1 to 20 carbon atoms, 1 to 12 carbon atoms, 1 to 10 carbon atoms, 1 to 6 carbon atoms, or 1 to 4 carbon atoms) plus optional groups selected from oxy, thio, —NR⁴—, methine, tertiary nitrogen, quaternary nitrogen, carbonyl, sulfonyl, sulfiryl, carbonyloxy, carbonylthio, carbonylimino, sulfonylimino, oxycarbonyloxy, iminocarbonylimino, oxycarbonylimino, or a combination thereof. Group R⁴ is hydrogen, alkyl (e.g., an alkyl having 1 to 10 carbon atoms, 1 to 6 carbon atoms, or 1 to 4 carbon atoms), aryl (e.g., an aryl having 6 to 12 carbon atoms such as phenyl or biphenyl), or aralkyl (e.g., an aralkyl having an alkyl group with 1 to 10 carbon atoms, 1 to 6 carbon atoms, or 1 to 4 carbon atoms and an aryl group with 6 to 12 carbon atoms such as phenyl). If the compound of Formula (I) has multiple Q groups, the Q groups can be the same or different. In many embodiments with multiple Q groups, these groups are the same.

In some embodiments, group Q includes an alkylene having at least 1 or at least 2 carbon atoms directly bonded to the —COO— group in Formula (I). The presence of such an alkylene group tends to provide stability against hydrolysis and other chemical transformations such as nucleophilic attack.

Some divalent Q groups are an alkylene group of formula —(CH₂)ₖ— where each variable k is independently an integer greater than 1, greater than 2, or greater than 5 For example, k can be an integer in the range of 1 to 30, in the range of 1 to 25, in the range of 1 to 20, in the range of 1 to 15, in the range of 2 to 15, in the range of 2 to 12, in the range of 1 to 10, in the range of 1 to 6, or in the range of 1 to 4. Specific examples include, but are not limited to, —CH₂— and —CH₂CH₂—. Such groups are typical for Q when R_{f} is a monovalent or divalent radical of a perfluoroalkane.

Some divalent Q groups include a single alkylene group directly bonded to one or more of the optional groups. Such groups can be of formula —(CO)N(R⁴)—(CH₂)ₖ— where the alkylene is bonded to a carbonylimino group, —O(CO)N(R⁴)—(CH₂)ₖ— where the alkylene is bonded to a oxycarbonylimino group, —(CO)S—(CH₂)ₖ— where the alkylene is linked to a carbonylthio, or —S(O)₂N(R⁴)—(CH₂)ₖ— where the alkylene is linked to a sulfonylimino group. The variable k and the group R⁴ are the same as described above. Some more specific groups include, for example, —(CO)NH(CH₂)₂—, or —O(CO)NH(CH₂)₂—. In these Q groups, the alkylene group is also bonded to the —C(R¹)₂— group.

Other divalent Q groups include two alkylene groups joined by one or more of the optional groups. Such groups can be, for example, of formula —(CH₂)ₖ—S—(CH₂)ₖ— where a thio group links two alkylene groups, —(CH₂)ₖ—O—(CH₂)ₖ— where an oxy group links two alkylene groups, —(CH₂)ₖ—S(O)₂—(CH₂)ₖ— where a sulfonyl group links two alkylene groups, —(CH₂)ₖO(CO)N(R⁴)—(CH₂)ₖ— where an oxycarbonylimino group links two alkylene groups, —(CH₂)ₖO(CO)O—(CH₂)ₖ— where an oxycarbonyloxy group links two alkylene groups, —(CH₂)ₖN(R⁴)₂⁺—(CH₂)ₖ— where a quaternary nitrogen group links two alkylene groups, and —(CO)NR⁴—(CH₂)ₖ—N(R⁴)₂⁺—(CH₂)ₖ— where a quaternary nitrogen group links two alkylene groups and where one of the alkylene groups is further bonded to a carbonylimino group. The positively charged quaternary nitrogen group is balanced with an anion that is not shown in the formula. The variable k and the group R⁴ in any of these groups are the same as described above. More specific divalent Q groups include, for example, —CH₂O(CH₂)₂—, —CH₂—O(CO)NH—(CH₂)₂—, —(CH₂)₃—S—(CH₂)₃—, —(CH₂)₂—N(CH₃)₂⁺—(CH₂)₂—, and —(CO)NH—(CH₂)₃—N(CH₃)₂⁺—(CH₂)₂—.

Still other divalent Q groups include more than two alkylene groups that are joined by two or more of the optional groups. Such groups can be, for example, of formula —CH₂O—(CH₂)ₖ—S—(CH₂)ₖ— with three alkylene groups linked by an oxy and thio group, —CH₂O—(CH₂)ₖ—SO—(CH₂)ₖ— with three alkylene groups linked by an oxy and sulfinyl, —CH₂O—(CH₂)ₖ—SO₂—(CH₂)ₖ— with three alkylene groups linked by an oxy and sulfonyl. The variable k is the same as described above. More specific examples include, but are not limited to, —CH₂O—CH₂CH₂CH₂—S—CH₂CH₂— and —CH₂O—CH₂CH₂—S—CH₂CH₂—. Other such groups can be, for example, of formula —(CO)—NR⁴—(CH₂)ₖ—NR⁴—(CH₂)ₖ—(CO)O—(CH₂)ₖ— where R⁴ and k are the same as described above. A carbonylimino group is linked to a first alkylene group that is linked to a second alkylene group with an imino group. The second alkylene group is linked to a third alkylene group with a carbonyloxy group. In this formula the carbonylimino group is linked to the R_{f} group. The variable k and the group R^{a} are the same as described above. A specific examples of this Q group is —(CO)—NH—(CH₂)₃—N(CH₃)—(CH₂)₂—(CO)O—(CH₂)₂—.

Trivalent Q groups typically include a methine group or a tertiary nitrogen atom as the branching site. Example trivalent Q groups include, but are not limited to, a methine-containing group such as

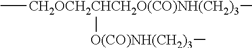

and tertiary nitrogen atom-containing group such as

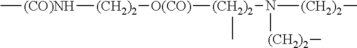

The tertiary nitrogen atom-containing groups are often directly bonded to three alkylene groups as shown in this last group Q.

Some Q groups include a quaternary nitrogen atom that imparts a positive charge to the fluorinated silane. Even with this positive charge, the fluorinated layer tends to be hydrophobic. The quaternary nitrogen is often directly bonded to two alkylene groups. Each of the remaining two groups bonded to the quaternary nitrogen are often independently hydrogen, alkyl (e.g., an alkyl having 1 to 10 carbon atoms, 1 to 6 carbon atoms, or 1 to 4 carbon atoms), aryl (e.g., an aryl with 6 to 12 carbon atoms such as phenyl), or aralkyl (e.g., an aralkyl with an alkyl group having 1 to 10 carbon atoms, 1 to 6 carbon atoms, or 1 to 4 carbon atoms and an aryl group having 6 to 12 carbon atoms such as phenyl). If Q includes a quaternary nitrogen atom, there is an anion present to balance the positive charge of the quaternary nitrogen atom. Suitable anions can be inorganic or organic and include, for example, halides (e.g., chloride, bromide, or iodide), carboxylate anions (e.g., acetate), sulfonates (e.g., CH₃OSO₂⁻), phosphate, sulfate, carbonate, and the like.

There is at least one group of formula —C(R¹)₂—Si(R²)₃₋ₓ(R³)— in each fluorinated silane of Formula (I) that is covalently bonded to each group Q. If R_{f} is monovalent and Q is either a single bond or a divalent group, there is a single group of formula —C(R¹)₂—Si(R²)₃₋ₓ(R³)—. If R_{f} is monovalent and Q is trivalent, there are two groups of formula —C(R¹)₂—Si(R²)₃₋ₓ(R³)ₓ. If R_{f} is divalent and Q is either a single bond or a divalent group, there are two groups of formula —C(R¹)₂—Si(R²)₃₋ₓ(R³)ₓ. If R^{f} is divalent and Q is trivalent, there are four groups of formula —C(R¹)₂—Si(R²)₃₋ₓ(R³)ₓ. Each group R¹ is independently hydrogen or alkyl. Suitable alkyl groups for R¹ often have 1 to 10 carbon atoms, 1 to 6 carbon atoms, 1 to 4 carbon atoms, or 1 to 3 carbon atoms. In many embodiments, each R¹ is hydrogen. Each group R² is independently hydroxyl or a hydrolyzable group. Each group R³ is independently a non-hydrolyzable group. The variable x is an integer equal to 0, 1, or 2.

In each group of formula —C(R¹)₂—Si(R²)₃₋ₓ(R³)ₓ, there can be one, two, or three R² groups. The R² group is the reaction site for reaction with the acid-sintered silica nanoparticles included in the primer layer. That is, the hydrolyzable group or hydroxyl group reacts with the surface of the acid-sintered silica nanoparticles to covalently attach the fluorinated silane to the primer layer resulting in the formation of a —Si—O—Si— bond. Suitable hydrolyzable R² groups include, for example, alkoxy, aryloxy, aralkyloxy, acyloxy, or halo groups. Suitable alkoxy groups often have 1 to 10 carbon atoms, 1 to 6 carbon atoms, 1 to 4 carbon atoms, or 1 to 3 carbon atoms. Suitable aryloxy groups often have 6 to 12 carbon atoms or 6 to 10 carbon atoms such as, for example, phenoxy. Suitable aralkyloxy group often have an alkoxy group with 1 to 10 carbon atoms, 1 to 6 carbon atoms, or 1 to 4 carbon atoms and an aryl group with 6 to 12 carbon atoms or 6 to 10 carbon atoms. An example aralkyloxy group has an alkoxy group with 1 to 4 carbon atoms with a phenyl group covalently attached to the alkoxy group. Suitable halo groups can be chloro, bromo, or iodo but are often chloro. Suitable acyloxy groups are of formula —O(CO)R^{b} where R^{b} is alkyl, aryl, or aralkyl. Suitable alkyl R^{b} groups often have 1 to 10 carbon atoms, 1 to 6 carbon atoms, or 1 to 4 carbon atoms. Suitable aryl R^{b} groups often have 6 to 12 carbon atoms or 6 to 10 carbon atoms such as, for example, phenyl. Suitable aralkyl R^{b} groups often have an alkyl group with 1 to 10 carbon atoms, 1 to 6 carbon atoms, or 1 to 4 carbon atoms that is substituted with an aryl having 6 to 12 carbon atoms or 6 to 10 carbon atoms such as, for example, phenyl. When there are multiple R² groups, they can be the same or different. In many embodiments, each R² is an alkoxy group.

If there are fewer than three R² group in each group of formula —C(R¹)₂—Si(R²)₃₋ₓ(R³)ₓ, there is at least one R³ group. The R³ group is a non-hydrolyzable group. Many non-hydrolyzable groups are alkyl, aryl, and aralkyl groups. Suitable alkyl groups include those having 1 to 10 carbon atoms, 1 to 6 carbon atoms, or 1 to 4 carbon atoms. Suitable aryl groups often have 6 to 12 carbon atoms or 6 to 10 carbon atoms such as phenyl or biphenyl. Suitable aralkyl groups often have an alkyl group with 1 to 10 carbon atoms, 1 to 6 carbon atoms, or 1 to 4 carbon atoms substituted with an aryl having 6 to 12 carbon atoms or 6 to 10 carbon atoms such as, for example, phenyl. When there are multiple R³ groups, these groups can be the same or different. In many embodiments, each R³ is an alkyl group.

Some specific fluorinated silanes where R_{f} is a monovalent or divalent radical of a perfluoroether or perfluoropolyether are of formula R_{f}—(CO)N(R⁴)—(CH₂)ₖ—CH₂—Si(R²)₃, of formula R_{f}—[(CO)N(R⁴)—(CH₂)ₖ—CH₂—Si(R²)₃]₂, or a mixture thereof. The variable k is the same as defined above. In some embodiments, k is in the range of 1 to 10, in the range of 1 to 6, or in the range of 1 to 4. Some more particular fluorinated silanes of formula R_{f}—(CO)N(R⁴)—CH₂)ₖ—CH₂—Si(R²)₃ include, but are not limited to, F(CF(CF₃)CF₂O)ₐCF(CF₃)—CONHCH₂CH₂CH₂Si(OCH₃)₃ where a is a variable in a range of 4 to 20 and CF₃OC₂F₄OC₂F₄OCF₂CONHC₃H₆Si(OEt)₃. A more particular example of formula R_{f}—[(CO)N(R⁴)—CH₂)ₖ—CH₂—Si(R²)₃]₂ is a compound of formula

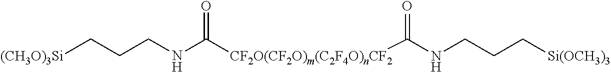

where n and m are each a variable in a range of about 9 to 10.

Some specific fluorinated silanes where R_{f} is a monovalent or divalent radical of a perfluoroalkane are of formula R_{f}—(CH₂)ₖ—CH₂—Si(R²)₃, or formula R_{f}—[(CH₂)ₖ—CH₂—Si(R₂)₃]₂, or a mixture thereof. The variable k is the same as defined above. More specific fluorinated silanes are of formula R_{f}—(CH₂)₂—Si(R²)₃, or formula R_{f}—[(CH₂)₂—Si(R₂)₃]₂, or a mixture thereof.

The above-described fluorinated silane compounds can be synthesized using standard techniques. For example, commercially available or readily synthesized perfluoropolyether ester or perfluoroether esters (or functional derivatives thereof) can be combined with a functionalized alkoxysilane, such as a 3-aminopropylalkoxysilane. Suitable synthesis methods are described, for example, in U.S. Pat. No. 3,250,808 (Moore), U.S. Pat. No. 3,646,085 (Barlett), U.S. Pat. No. 3,810,874 (Mitsch et al.), U.S. Pat. No. 7,294,731 (Flynn et al.), and CA Patent No. 725747 (Moore). The methods can be used as described or adapted to prepare compounds in accordance with the above description. It will be understood that functional groups other than esters can be used with equal facility to incorporate silane groups into a perfluoropolyether or perfluoroether.

Perfluoropolyether diesters and perfluoroether diesters can be prepared, for example, through direct fluorination of a hydrocarbon ether diester or polyether diester. Direct fluorination involves contacting the hydrocarbon ether diester or polyether diester with fluorine (F₂) in a diluted form. The hydrogen atoms of the hydrocarbon ether diester or polyether diester will be replaced with fluorine atoms, thereby generally resulting in the corresponding perfluoroether diester or perfluoropolyether diester. The diesters are typically not used directly but are converted to diesters of formula CH₃O—(CO)—R_{f}—(CO)—OCH₃. Direct fluorination methods are disclosed in, for example, U.S. Pat. No. 5,578,278 (Fall et al.) and U.S. Pat. No. 5,658,962 (Moore et al.).

For certain embodiments, the number average molecular weight of the R_{f} group of the fluorinated silane compounds can be at least 750 grams/mole, at least 800 grams/mole, at least 900 grams/mole, or at least 1000 grams/mole. In some embodiments, higher number average molecular weights can further enhance durability. The higher weight fluorinated silanes can, for example, protect surfaces from moisture and hydrolysis. Generally, for ease of use and application, the number average molecular weight of the R_{f} group is often no greater than 10,000 grams/mole, no greater than 7,500 grams/mole, no greater than 6000 grams/mole, no greater than 5000 grams/mole, no greater than 4000 grams/mole, or no greater than 3000 grams/mole. In some embodiments, the number average molecular weight is in the range of 1000 to 6000 grams/mole, in the range of 2000 to 5000 grams/mole, or in the range of 3000 to 4000 grams/mole.

Perfluoropolyether silanes typically include a distribution of oligomers and/or polymers. The amount of perfluoropolyether silane (in such a distribution) having a perfluoropolyether segment with a number average molecular weight less than about 750 is no greater than about 10 weight percent, no greater than 5 weight percent, no greater than 2 weight percent, no greater than 1 weight percent, no greater than 0.5 weight percent, no greater than 0.2 weight percent, no greater than 0.1 weight percent, or no greater than 0.01 weight percent based on a total amount of perfluoropolyether silane in the distribution.

The fluorinated silane that is reacted with the surface of the acid-sintered silica nanoparticles in the primer layer can be a single fluorinated silane or a mixture of fluorinated silanes. For example, a mixture of a first fluorinated silane having a monovalent R_{f} group and a second fluorinated silane having a divalent R_{f} group can be used. The mixture can include a weight ratio of the first fluorinated silane with a monovalent R_{f} group to the second fluorinated silane having a divalent R_{f} group that is at least 10:90, at least 20:80, at least 30:70, at least 40:60, or at least 50:50. This weight ratio is often no greater than 99:1, no greater than 97:3, no greater than 95:5, no greater than 90:10, or no greater than 80:20.

The fluorinated silanes typically have a relatively long shelf life in the absence of moisture. The fluorinated silanes are often in the form of a relatively viscous liquid that can be used in the surface treatment of the primer layer in neat form (e.g., the fluorinated silane can be applied by chemical vapor deposition). Alternatively, the fluorinated silane can be mixed with one or more organic solvents and/or one or more other optional compounds. The composition containing the fluorinated silane that is applied to the surface of the primer layer is referred to as a “fluorinated layer coating composition”. The fluorinated layer coating composition is used to form the fluorinated layer.

Suitable organic solvents for use in the fluorinated layer coating composition include, but are not limited to, aliphatic alcohols such as, for example, methanol, ethanol, and isopropanol; ketones such as, for example, acetone and methyl ethyl ketone; esters such as, for example, ethyl acetate and methyl formate; ethers such as, for example, diethyl ether, diisopropyl ether, methyl t-butyl ether, and dipropylene glycol monomethyl ether (DPM); alkanes such as, for example, heptane, decane, and other paraffinic (i.e., oleofinic) solvents; perfluorinated hydrocarbons such as, for example, perfluorohexane and perfluorooctane; fluorinated hydrocarbons such as, for example, pentafluorobutane; hydrofluoroethers such as, for example, methyl perfluorobutyl ether and ethyl perfluorobutyl ether; and the like; and combinations thereof. Preferred solvents often include aliphatic alcohols, perfluorinated hydrocarbons, fluorinated hydrocarbons, hydrofluoroethers, or combinations thereof. In some embodiments, the surface treatment composition contains aliphatic alcohols, hydrofluoroethers, or combinations thereof. In other embodiments, the fluorinated layer coating composition contains hydrofluoroethers or combinations thereof.

Some suitable fluorinated solvents that are commercially available include, for example, those commercially available from 3M Company (Saint Paul, Minn.) under the trade designation 3M NOVEC ENGINEERED FLUID (e.g., 3M NOVEC ENGINEERED FLUID 7100, 7200DL, and 7500).

If an organic solvent is used, the fluorinated layer coating compositions often contain an amount of the organic solvent that can dissolve or suspend at least about 0.01 percent by weight of the fluorinated silane based on a total weight of the fluorinated layer coating composition. In some embodiments, it can be desirable that the organic solvent or mixture of organic solvents have water solubility equal to at least about 0.1 percent by weight, and for certain of these embodiments, acid solubility equal to at least about 0.01 weight percent.

When an organic solvent is used, useful concentrations of the fluorinated silane in the fluorinated layer coating composition can vary over a wide range. For example, the fluorinated layer coating composition can include at least 0.01 weight percent, at least 0.1 weight percent, at least 1 weight percent, at least 5 weight percent, at least 10 weight percent, at least 25 weight percent, at least 50 weight percent, at least 75 weight percent, at least 80 weight percent, at least 85 weight percent, at least 90 weight percent, or at least 95 weight percent fluorinated silane based on a total weight of the fluorinated layer coating composition. The amount often depends on the viscosity of the fluorinated silane, the application method utilized, the nature of the substrate, and the desired surface characteristics.

The fluorinated layer coating composition can include other optional compounds. For example, a crosslinker can be added. The crosslinker is typically added when there are multiple silyl groups on the fluorinated silane of Formula (I). The crosslinker can react with any reactive silyl groups of the fluorinated silane that have not reacted with a surface of the primer layer. Any crosslinker that can react with the fluorinated silane can be used. The crosslinker can react, for example, with multiple fluorinated silanes having remaining reactive silyl groups. Alternatively, a first group of the crosslinker can react with the surface of an acid-sintered silica nanoparticle and a second group of the crosslinker can react with a fluorinated silane to covalently attach the fluorinated silane to the primer layer. In this alternative reaction, the crosslinker functions as a linker between the fluorinated silane and the primer layer.

Some crosslinkers have multiple reactive silyl groups (silyl groups having at least one hydroxyl or hydrolyzable group). These crosslinkers can be polymers with multiple reactive silyl groups. Alternatively, these crosslinkers can be of Formula (II) or Formula (III).

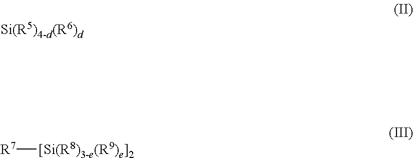

In Formulas (II) or (III), each R⁵ or R⁸ group is independently hydroxyl or a hydrolyzable group and each R⁶ or R⁹ group is independently a non-hydrolyzable group. The variable d in Formula (II) is an integer equal to 0, 1, 2, or 3. The variable e in Formula (III) is an integer equal to 0, 1, or 2. The group R⁷ in Formula (III) is an alkylene having 1 to 10 carbon atoms, 1 to 6 carbon atoms, 1 to 4 carbon atoms, or 1 to 3 carbon atoms.

Each R⁵ or R⁸ group in Formulas (II) or (III) respectively is a hydrolyzable group or hydroxyl group. This group can react with a remaining reactive silyl in a fluorinated silane. Reacting multiple such R⁵ or R⁸ groups with multiple fluorinated silanes can result in the crosslinking of the fluorinated silanes. Alternatively, one such group can also react with the surface of a silica nanoparticle and another such group can react with a fluorinated silane to covalently attach the fluorinated silane to the primer layer. Suitable hydrolyzable R⁵ or R⁸ groups include, for example, alkoxy, aryloxy, aralkyloxy, acyloxy, or halo groups. Suitable alkoxy groups often have 1 to 10 carbon atoms, 1 to 6 carbon atoms, 1 to 4 carbon atoms, or 1 to 3 carbon atoms. Suitable aryloxy groups often have 6 to 12 carbon atoms or 6 to 10 carbon atoms such as, for example, phenoxy. Suitable aralkyloxy group often have an alkoxy group with 1 to 10 carbon atoms, 1 to 6 carbon atoms, or 1 to 4 carbon atoms that is substituted with an aryl group with 6 to 12 carbon atoms or 6 to 10 carbon atoms. An example aralkyloxy group has an alkoxy group with 1 to 4 carbon atoms with a phenyl group covalently attached to the alkoxy group. Suitable halo groups can be chloro, bromo, or iodo but are often chloro. Suitable acyloxy groups are of formula —O(CO)R^{b} where R^{b} is alkyl, aryl, or aralkyl. Suitable alkyl R^{b} groups often have 1 to 10 carbon atoms, 1 to 6 carbon atoms, or 1 to 4 carbon atoms. Suitable aryl R^{b} groups often have 6 to 12 carbon atoms or 6 to 10 carbon atoms such as, for example, phenyl. Suitable aralkyl R^{b} groups often have an alkyl group with 1 to 10 carbon atoms, 1 to 6 carbon atoms, or 1 to 4 carbon atoms that is substituted with an aryl having 6 to 12 carbon atoms or 6 to 10 carbon atoms such as, for example, phenyl. When there are multiple R⁵ or R⁸ groups, these groups can be the same or different. In many embodiments, each R⁵ or R⁸ is an alkoxy group.

Each R⁶ or R⁹ group in Formulas (II) or (III) respectively is a non-hydrolyzable group. Many non-hydrolyzable groups are alkyl, aryl, and aralkyl groups. Suitable alkyl groups include those having 1 to 10 carbon atoms, 1 to 6 carbon atoms, or 1 to 4 carbon atoms. Suitable aryl groups often have 6 to 12 carbon atoms or 6 to 10 carbon atoms such as phenyl or biphenyl. Suitable aralkyl groups often have an alkyl group with 1 to 10 carbon atoms, 1 to 6 carbon atoms, or 1 to 4 carbon atoms substituted with an aryl having 6 to 12 carbon atoms or 6 to 10 carbon atoms such as, for example, phenyl. When there are multiple R⁶ or R⁹ groups, they can be the same or different. In many embodiments, each R⁶ or R⁹ is an alkyl group.

Example crosslinkers include, but are not limited to, tetraalkoxysilanes such as tetraethoxysilane (TEOS), bis(triethoxysilyl)ethane, and poly(diethoxysilane).

The amount of crosslinker included in the fluorinated layer coating composition can be any suitable amount depending, for example, on the particular application and the desired properties. In many embodiments, the fluorinated layer coating composition can include up to 75 weight percent, up to 70 weight percent, up to 60 weight percent, up to 50 weight percent, up to 40 weight percent, up to 30 weight percent, up to 20 weight percent, or up to 10 weight percent of the crosslinker based on a total weight of the fluorinated layer coating composition. For example, the crosslinker can be in the range of 1 to 75 weight percent, 1 to 70 weight percent, 1 to 60 weight percent, 1 to 50 weight percent, 1 to 40 weight percent, 1 to 30 weight percent, 1 to 20 weight percent, or 1 to 10 weight percent.

Minor amounts of other optional components can be added to the fluorinated layer coating composition that may impart desirable properties, that may be desirable for particular curing methods or conditions, or that may be desirable for particular surface treatment applications. Examples of other optional components include, but are not limited to, catalysts (including the moisture curing catalysts described below), initiators, surfactants, stabilizers, anti-oxidants, flame retardants, ultraviolet (UV) absorbers, radical quenchers, and the like, and mixtures thereof.

In a second aspect, a method of making an article is provided. The method includes providing a substrate and forming a primer layer on a surface of the substrate. The primer layer contains a plurality of acid-sintered silica nanoparticles arranged to form a continuous, three-dimensional porous network. The method further includes covalently bonding a hydrophobic fluorinated layer to the primer layer by reacting a surface of the acid-sintered silica nanoparticles in the primer layer with a fluorinated silane. The fluorinated silane contains both a reactive silyl group and a fluorinated group such as a perfluorinated group. In many embodiments, the fluorinated silane used to form the hydrophobic fluorinated layer is of Formula (I).

The fluorinated silane react with a surface of the acid-sintered silica nanoparticles included in the primer layer to form a —Si—O—Si— bond between the primer layer and the hydrophobic fluorinated layer. The resulting hydrophobic fluorinated layer is attached to the substrate through the primer layer. The combination of the primer layer and the hydrophobic fluorinated layer can be used to impart a degree of hydrophobicity and/or oleophobicity to a variety of substrates or to further enhance the hydrophobicity and/or oleophobicity of a variety of substrates.

The fluorinated silane in applied to the primer layer as a fluorinated layer coating composition. The fluorinated layer coating composition can be applied to the primer layer using any suitable application method. The application method often involves forming a coating layer by dip coating, spin coating, spray coating, wiping, roll coating, brushing, spreading, flow coating, vapor deposition, or the like, or combinations thereof.

Typically, the fluorinated layer coating composition can be applied to the primer layer on the substrate such that after curing, a fluorinated layer is formed over the primer layer. That is, the primer layer is positioned between the substrate and the fluorinated layer. The fluorinated layer can be a monolayer or more in thickness. The thickness of the fluorinated layer, for example, can be in the range of 0.001 to 1 micrometer, in the range of 0.001 to 0.10 micrometers, or in the range of 0.01 to 0.1 micrometers.

After application to the primer layer, the fluorinated layer coating composition can be cured by exposure to heat and/or moisture. Curing attaches the fluorinated silane to the primer layer. Curing results in the formation of the —Si—O—Si— bond between the fluorinated silane and the acid-sintered silica nanoparticles in the primer layer. If a crosslinker is included in the fluorinated layer coating composition, these materials can react with any remaining reactive silyl groups on the fluorinated silane. Moisture cure can be affected at temperatures ranging from room temperature (for example, 20° C. to 25° C.) up to about 80° C. or more. Moisture curing times can range from a few minutes (for example, at the higher temperatures such as 80° C. or higher) to hours (for example, at the lower temperatures such as room temperature).

For the preparation of a durable coating, sufficient water typically can be present to cause hydrolysis of the hydrolyzable groups described above, so that condensation to form —Si—O—Si— groups can occur (and thereby curing can be achieved). The water can be, for example, present in the fluorinated layer coating composition, adsorbed on the substrate surface, or in the ambient atmosphere. Typically, sufficient water can be present for the preparation of a durable coating if the coating method is carried out at room temperature in an atmosphere containing water (for example, an atmosphere having a relative humidity of about 30 percent to about 50 percent). The fluorinated silane can undergo chemical reaction with the surface of the acid-sintered silica nanoparticles in the primer layer to form a durable coating through the formation of covalent bonds (including bonds in —Si—O—Si-groups).

In some embodiments, a moisture curing catalyst is used. Suitable moisture curing catalysts are well-known in the art and include, for example, ammonia, N-heterocyclic compounds, monoalkylamines, dialkylamines, or trialkylamines, organic or inorganic acids, metal carboxylates, metal acetylacetonate complexes, metal powders, peroxides, metal chlorides, organometallic compounds, and the like, and combinations thereof. When used, the moisture curing catalysts can be present in amounts in a range of 0.1 to 10 weight percent, in a range of 0.1 to about 5 weight percent, or in a range of 0.1 to about 2 weight percent based on a total weight of the fluorinated layer coating composition.

Example N-heterocyclic compounds that can function as moisture curing catalysts include, but are not limited to, 1-methylpiperazine, 1-methylpiperidine, 4,4′-trimethylenedipiperidine, 4,4′-trimethylene-bis(1-methylpiperidine), diazobicyclo[2.2.2]octane, cis-2,6-dimethylpiperazine, and the like, and combinations thereof.

Example monoalkylamines, dialkylamines, and trialkylamines that can function as moisture curing catalysts include, but are not limited to, methylamine, dimethylamine, trimethylamine, phenylamine, diphenylamine, triphenylamine, DBU (that is, 1,8-diazabicyclo[5.4.0]-7-undecene), DBN (that is, 1,5-diazabicyclo[4.3.0]-5-nonene), 1,5,9-triazacyclododecane, 1,4,7-triazacyclononane, and the like, and combinations thereof.

Example organic or inorganic acids that can function as moisture curing catalysts include, but are not limited to, acetic acid, formic acid, triflic acid, perfluorobutyric acid, propionic acid, butyric acid, valeric acid, maleic acid, stearic acid, citric acid, hydrochloric acid, nitric acid, sulfuric acid, phosphoric acid, chloric acid, hypochlorous acid, and the like, and combinations thereof.

The fluorinated layer coating composition is typically applied to the primer layer at room temperature (typically in a range of 15° C. to 30° C. or in a range of 20° C. to 25° C.). Alternatively, the fluorinated layer coating composition can be applied to the primer layer that has been preheated at an elevated temperature such as, for example, in a range of 40° C. to 300° C., in a range of 50° C. to 200° C., or in a range of 60° C. to 150° C. Following application of the fluorinated layer coating composition, the resulting coating can be dried and then cured at ambient temperature (for example, in the range of 15° C. to 30° C. or in the range of 20° C. to 25° C.) or at an elevated temperature (for example, in the range of 40° C. to 300° C., in the range of 50° C. to 200° C., or in the range of 50° C. to 100° C.) for a time sufficient for the curing to take place.

The resulting articles have a hydrophobic coating. The contact angle for water is often equal to at least 85 degrees, at least 90 degrees, at least 95 degrees, at least 100 degrees, at least 105 degrees, at least 110 degrees, or at least 115 degrees. The coatings are durable and can be subjected to repeated rubbing or abrasion while retaining the same contact angle for water. The coatings can be subjected to repeated rubbing and/or cleaning and retain their hydrophobic characteristics.

The hydrophobic character of the resulting article can be varied by selection of the size of the silica nanoparticles used to form the primer layer and by selection of the specific fluorinated silane that is used to form the fluorinated layer. For example, the hydrophobic character can often be increased by preparing a rougher primer layer surface. A rougher surface tends to result from a mixture of silica particles with different sizes, shapes, or a mixture thereof. Additionally, the hydrophobic character can often be increased by selection of a fluorinated silane. A more hydrophobic fluorinated group (e.g., a more hydrophobic perfluorinated group) can be used to increase the hydrophobic character of the resulting article.

The fluorinated silanes are covalently bonded to the primer layer through a —Si—O—Si— bond. The use of the primer layer allows durable coatings of fluorinated materials on otherwise hydrophobic substrates. That is, the fluorinated silanes can be attached to substrates that normally would not be compatible with fluorinated silanes (i.e., substrates that are not capable of forming a —Si—O—Si— bond with the fluorinated silanes). Coatings based on fluorinated silanes can be extended beyond substrates such as glass and ceramic materials with hydroxyl groups on the surface. More specifically, the fluorinated silanes can be attached through the primer layer to surfaces such as various metals (e.g., aluminum and stainless steel) and various polymeric materials (e.g., polycarbonate, poly(methyl methacrylate), ABS, and the like) that do not have surface groups capable of reacting with the fluorinated silanes. The formation of the —Si—O—Si— between the fluorinated silanes and the acid-sintered silica nanoparticles in the primer layer enhances the durability of the fluorinated coatings. The fluorinated coatings tend to provide a surface that is easy to clean, smudge resistant, and fingerprint resistant.

Various items are described that are articles or methods of making articles.

Item 1 is an article that that includes (a) a substrate, (b) a primer layer attached to a surface of the substrate, and (c) a hydrophobic fluorinated layer attached to the primer layer. The primer layer contains a plurality of acid-sintered silica nanoparticles arranged to form a continuous, three-dimensional porous network. The hydrophobic fluorinated layer contains the reaction product of a fluorinated silane with a surface of the acid-sintered silica nanoparticles in the primer layer. The fluorinated silane contains both a reactive silyl group and a fluorinated group.

Item 2 is an article of item 1, wherein the fluorinated group is a perfluorinated group.

Item 3 is an article of item 1 or 2, wherein the fluorinated silane is of Formula (I).

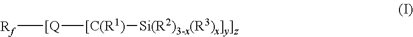

In Formula (I), the group R_{f} is a z-valent radical of a polyfluoroether, polyfluoropolyether, or perfluoroalkane; Q is a divalent or trivalent linking group; each R¹ is independently hydrogen or alkyl; each R² is independently hydroxyl or a hydrolyzable group; each R³ is independently a non-hydrolyzable group; each x is an integer equal to 0, 1, or 2; y is an integer equal to 1 or 2; and z is an integer equal to 1 or 2.

Item 4 is an article of item 3, wherein Q comprises an alkylene.

Item 5 is an article of item 3 or 4, wherein Q comprises at least one alkylene and further comprises at least one oxy, thio, —NR⁴—, methine, tertiary nitrogen, quaternary nitrogen, carbonyl, sulfonyl, sulfiryl, carbonyloxy, carbonylthio, carbonylimino, sulfonylimino, oxycarbonyloxy, iminocarbonylimino, oxycarbonylimino, or a combination thereof. Group R⁴ is hydrogen, alkyl, aryl, or aralkyl.

Item 6 is an article of any one of items 1 to 5, wherein the substrate is a polymeric material or a metal.

Item 7 is an article of any one of items 1 to 6, wherein the silica nanoparticles are a mixture of spherical and acicular nanoparticles.

Item 8 is an article of any one of items 1 to 7, wherein the primer layer comprises a reaction product of acid-sintered silica nanoparticles and a crosslinking agent having at least two reactive silyl groups.

Item 9 is an article of any one of items 1 to 8, wherein the primer layer is formed from a silica sol acidified with an acid having a pKa less than 3.5 to a pH in a range of 2 to 5.

Item 10 is an article of any one of items 3 to 9, wherein the fluorinated silane is of Formula (Ia).

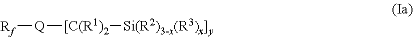

Item 11 is an article of any one of items 3 to 9, wherein the fluorinated silane is of Formula (Ib).

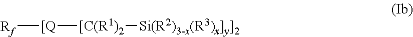

Item 12 is an article of any one of items 1 to 11, wherein the article is anti-reflective.

Item 13 is an article of any one of item 3 to 12, wherein Q is —(CO)N(R⁴)—(CH₂)ₖ— where k is an integer in a range of 1 to 10 and R⁴ is hydrogen, alkyl, aryl, or arakyl.

Item 14 is an article of any one of items 3 to 9, wherein the fluorinated silane comprises a compound of formula Rᵣ(CO)N(R⁴)—(CH₂)ₖ—CH₂—Si(R²)₃ where k in an integer in a range of 1 to 10.

Item 15 is an article of item 14, wherein the fluorinated silane is a mixture of compounds of formula F(CF(CF₃)CF₂O)ₐCF(CF₃)—CONHCH₂CH₂CH₂Si(OCH₃)₃ where a is a variable in a range of 4 to 20.

Item 16 is an article of item 14, wherein the fluorinated silane comprises CF₃OC₂F₄OC₂F₄OCF₂CONHC₃H₆Si(OEt)₃.

Item 17 is an article of any one of items 3 to 9, wherein the fluorinated silane comprises a compound of formula R_{f}—[(CO)N(R⁴)—(CH₂)ₖ—CH₂—Si(R²)₃]₂ where k in an integer in a range of 1 to 10.

Item 18 is an article of item 17, wherein the fluorinated silane is a compound of formula

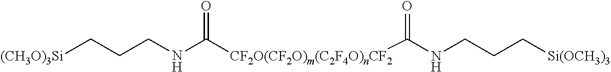

where n and m are each a variable in a range of about 9 to 10.

Item 19 is an article of any one of items 3 to 9, wherein the fluorinated silane comprises a first compound of formula R_{f}—(CO)N(R⁴)—(CH₂)ₖ—CH₂—Si(R²)₃ and a second compound of formula R_{f}—[(CO)N(R⁴)—(CH₂)ₖ—CH₂—Si(R²)₃]₂ where k is an integer in a range of 1 to 10.

Item 20 is an article of any one of items 3 to 9, wherein the fluorinated silane is crosslinked.

Item 21 is a method of making an article. The method includes providing a substrate and forming a primer layer on a surface of the substrate. The primer layer contains a plurality of acid-sintered silica nanoparticles arranged to form a continuous, three-dimensional porous network. The method further includes attaching a hydrophobic fluorinated layer to the primer layer by reacting a surface of the acid-sintered silica nanoparticles in the primer layer with a fluorinated silane. The fluorinated silane contains both a reactive silyl group and a fluorinated group.

Item 22 is a method of item 21, wherein the fluorinated group is a perfluorinated group.

Item 23 is a method of item 21 or 22, wherein the fluorinated silane is of Formula (I).

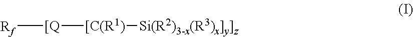

In Formula (I), R_{f} is a z-valent radical of a polyfluoroether, polyfluoropolyether, or perfluoroalkane; Q is a divalent or trivalent linking group; each R¹ is independently hydrogen or alkyl; each R² is independently hydroxyl or a hydrolyzable group; each R³ is independently a non-hydrolyzable group; each x is an integer equal to 0, 1, or 2; y is an integer equal to 1 or 2; and z is an integer equal to 1 or 2.

Item 24 is a method of item 23, wherein Q comprises an alkylene.

Item 25 is a method of item 23, wherein Q comprises at least one alkylene and further comprises at least one oxy, thio, —NR⁴—, methine, tertiary nitrogen, quaternary nitrogen, carbonyl, sulfonyl, sulfiryl, carbonyloxy, carbonylthio, carbonylimino, sulfonylimino, oxycarbonyloxy, iminocarbonylimino, oxycarbonylimino, or a combination thereof. Group R⁴ is hydrogen, alkyl, aryl, or aralkyl.

### EXAMPLES

Objects and advantages of this invention are further illustrated by the following examples, but the particular materials and amounts thereof recited in these examples, as well as other conditions and details, should not be construed to unduly limit this invention. These examples are for illustrative purposes only and are not meant to be limiting on the scope of the appended claims.

### GLOSSARY OF MATERIALS

“NALCO 1115” refers to an aqueous colloidal spherical silica dispersion with 16.5 weight percent solids (nominally 16 weight percent solids) that is commercially available from NALCO Chemical Company (Naperville, Ill.). The average particle size is approximately 4 nanometers.

“NALCO 1050” refers to an aqueous colloidal spherical silica dispersion with 50.4 weight percent solids (nominally 50 weight percent solids) that is commercially available from NALCO Chemical Company (Naperville, Ill.). The average particle size is approximately 20 nanometers.

“NALCO TX11561” refers to an aqueous colloidal spherical silica dispersion with 41.5 weight percent solids (nominally 41 weight percent solids) that is commercially available from NALCO Chemical Company (Naperville, Ill.). The average particle size is approximately 75 nanometers.

“NALCO DVSZN004” refers to an aqueous colloidal spherical silica dispersion with 41.2 weight percent solids (nominally weight 41 percent solids) that is commercially available from NALCO Chemical Company (Naperville, Ill.). The average particle size is approximately 42 nanometers.

“NALCO 2329” refers to an aqueous colloidal spherical silica dispersion with 39.5 weight percent solids (nominally 40 percent solids) that is commercially available from NALCO Chemical Company (Naperville, Ill.). The average particle size is approximately 92 nanometers.

“NALCO 2326” refers to an aqueous colloidal spherical silica dispersion with 39.5 weight percent solids (nominally 40 weight percent solids) that is commercially available from Nissan Chemical Company (Houston, Tex.). The average particle size is approximately 5 nanometers.

“SNOWTEX ST-UP” refers to an aqueous colloidal non-spherical silica dispersion with weight percent solids (nominally 21 weight percent solids) that is commercially available from Nissan Chemical Company (Houston, Tex.). The particles have an average width of approximately 9 to 15 nanometers and an average length of approximately 80 to 150 nanometers.

“SNOWTEX ST-PS-M” refers to an aqueous colloidal non-spherical silica dispersion with 21.2 weight percent solids (nominally 21 weight percent solids) that is commercially available from Nissan Chemical Company (Houston, Tex.). The particles have an average width of approximately 18 to 25 nanometers and an average length of approximately 80 to 150 nanometers.

“SILCO LI518” refers to an aqueous colloidal spherical silica dispersion with 18.8 weight percent solids (nominally 18 weight percent solids) that is commercially available from Silco International Inc (Portland, Oreg.). The average particle size is approximately 5 nanometers.

“3M NOVEC ENGINEERED FLUID 7100” refers to a hydrofluoroether solvent that is commercially available from 3M Company (Saint Paul, Minn.).

“3M NOVEC ENGINEERED FLUID 7200DL” refers to a hydrofluoroether solvent that is commercially available from 3M Company (Saint Paul, Minn.).

“3M NOVEC ENGINEERED FLUID 7500” refers to a hydrofluoroether solvent that is commercially available from 3M Company (Saint Paul, Minn.).

“HFPO—(CO)OCH₃” refers to a compound of formula F(CF(CF₃)CF₂O)ₐCF(CF₃)—(CO)OCH₃ where the variable a has an average value in the range of 4 to 20. This material, which is a mixture of compounds with different values of the variable a, can be prepared according to the method described in U.S. Pat. No. 3,250,808 (Moore et al.), the description of which is incorporated herein by reference, with purification by fractional distillation.

“HFPO-Silane” refers a compound of formula F(CF(CF₃)CF₂O)ₐCF(CF₃)—CONHCH₂CH₂CH₂Si(OCH₃)₃ where the variable a is in the range of 4 to 20. This material was prepared by charging HFPO—COOCH₃ (20 grams, 0.01579 mole) and NH₂CH₂CH₂CH₂—Si(OCH₃)₃ (2.82 grams, 0.01579 mole) under a N₂ atmosphere into a 100 mL 3-necked, round bottom flask equipped with a magnetic stir bar, nitrogen (N₂) inlet, and reflux condenser. The reaction mixture was heated at 75° C. for 12 hours. The reaction was monitored by infrared (IR) spectroscopy; after the disappearance of the ester peak, the resulting clear, viscous oil was kept under vacuum for another 8 hours and used as such.

“PPFO-Disilane” refers to an α,ω-poly(perfluorooxyalkylene)disilane was prepared essentially as described in U.S. Pat. No. 3,950,588 (McDougal et al.).

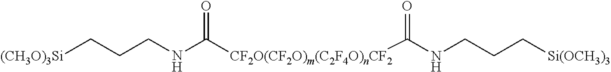

The variables n and m are in the range of about 9 to 10.

“CF₃OC₂F₄OC₂F₄OCF₂CONHC₃H₆Si(OEt)₃” refers to a fluorosilane that is prepared by initially preparing the intermediate CF₃OC₂F₄OC₂F₄OCF₂COOCH₃ using a procedure similar to that described in paragraph [0128] of U.S. Patent Application Publication 2003/0226818 (Dunbar et al.). This intermediate was converted to the silane by reacting with NH₂(CH₂)₃Si(OEt)₃ as described in U.S. Pat. No. 6,277,485 (Invie et al.).

“BTEOSE” refers to bis(triethoxysilyl)ethane that was obtained from Gelest (Morrisville, Pa.).

“PDES” refers to poly(diethoxysiloxane) that was obtained from Gelest (Morrisville, Pa.).

(Heptafluoro-1,1,2,2-tetrahydrodecyl)dimethylchlorosilane was obtained from Gelest (Morrisville, Pa.).

(Tridecafluoro-1,1,2,2-tetrahydrooctyl)dimethylchlorosilane was obtained from Gelest (Morrisville, Pa.).

(Heptafluoro-1,1,2,2-tetrahydrodecyl)trichlorosilane was obtained from Gelest (Morrisville, Pa.).

“Stainless steel coupon” refers to a coupon of stainless steel (304, #8 polished) that was obtained from Metal Depot (La Mirada, Calif.).

“Glass plate” refers to a float glass pane that was obtained from Cardinal Glass Industries (Eden Prairie, Minn.).

The PET (polyethylene terephthalate) film was SCOTHPAR POLYESTER from 3M Company (Saint Paul, Minn.). The thickness of the film was 50 micrometers.

All solvents were standard reagent grade that were obtained from commercial sources and that were used without further purification unless specified otherwise.

### Test Methods

### Method for Measuring Contact Angles

The coated substrate samples prepared as described in the following examples and comparative examples were rinsed for 1 minute by hand agitation in isopropyl alcohol (IPA). The IPA was allowed to evaporate before measuring water (H₂O) contact angles (using water as the wetting liquid).

Measurements of water contact angles were made using deionized water filtered through a filtration system (obtained from Millipore Corporation of Billerica, Mass.) on a video contact angle analyzer (available as product number VCA-2500XE from AST Products of Billerica, Mass.). Reported values were the averages of measurements on at least three drops measured on the right and left sides of each drop. Drop volumes were 1 microliter for static contact angle measurements and 1 to 3 microliters for advancing and receding contact angle measurements.

A similar process was used for measuring hexadecane (HD) contact angles.

### Abrasion Testing—Method 1

A TABER 5900 liner abrader (obtained from Taber Industries of North Tonawanda, N.Y.) was fitted with a 2.5 centimeter (cm) button covered with a KIMBERLY-CLARK L-30 WYPALL towel (obtained from Kimberly Clark of Roswell, Ga.) and a 5.1 cm by 5.1 cm crock cloth (obtained from Taber Industries, North Tonawanda, N.Y.). The samples were abraded for 5,000 or 10,000 cycles at a rate of 75 cycles/minute (1 cycle consisted of a forward wipe followed by a backward wipe) with a force of 10 Newtons (N) and a stroke length of 5.1 cm.

### Abrasion Testing—Method 2

A TABER 5750 liner abrader (obtained from Taber Industries of North Tonawanda, N.Y.) was fitted with a 2.5 cm button covered with a KIMBERLY-CLARK L-30 WYPALL towel (obtained from Kimberly Clark of Roswell, Ga.) and a 5.1 cm by 5.1 cm crock cloth (obtained from Taber Industries, North Tonawanda, N.Y.). The samples were abraded for 300 cycles at a rate of 30 cycles/minute (1 cycle consisted of a forward wipe followed by a backward wipe) with a force of 10 N and a stroke length of 6.4 cm.

### Primer Layer Coating Composition 1 (PLC1)

The colloidal silica dispersion NALCO 1115 was diluted to 2.5 weight percent solids with water and acidified with 3 M HNO₃ to a pH of 2.5.

### Primer Layer Coating Composition 2 (PLC2)

The colloidal silica dispersion NALCO 1050 was diluted to 2.5 weight percent solids with water and acidified with 3 M HNO₃ to a pH of 2.5. FIG. 1A is the transmission electron micrograph of a primer layer formed without the addition of acid. FIG. 1B is the transmission electron micrograph of a primer layer formed after the addition of acid.

### Primer Layer Coating Composition 3 (PLC3)

The colloidal silica dispersion NALCO TX11561 was diluted to 2.5 weight percent solids with water and acidified with 3 M HNO₃ to a pH of 2.5.

### Primer Layer Coating Composition 4 (PLC4)

The colloidal silica dispersions NALCO 2329 and NALCO 2326 were mixed in a 4:1 ratio (w/w) based on weight, diluted to 2.5 weight percent solids with water, and acidified with 3 M HNO₃ to a pH of 2.5.

### Primer Layer Coating Composition 5 (PLC5)

The colloidal silica dispersion SNOWTEX ST-UP was diluted to 2.5 weight percent solids with water and acidified with 3 M HNO₃ to a pH of 2.5.

### Primer Layer Coating Composition 6 (PLC6)

The colloidal silica dispersion SNOWTEX ST-PS-M was diluted to 2.5 weight percent solids with water and acidified with 3 M HNO₃ to a pH of 2.5.

### Primer Layer Coating Composition 7 (PLC7)

The colloidal silica dispersion NALCO 1115 was diluted to 0.75 weight percent solids with water and acidified with 1.5 M HNO₃ to a pH of 2.5.

### Primer Layer Coating Composition 8 (PLC8)

The colloidal silica dispersion SILCO LI518 was diluted to 0.75 weight percent solids with water and acidified with 1.5 M HNO₃ to a pH of 2.5.

### Primer Layer Coating Composition 9 (PLC9)

The colloidal silica dispersion NALCO 1115 was diluted to 0.5 weight percent solids with water and acidified with 1.5 M HNO₃ to a pH of 2.5.

### Primer Layer Coating Composition 10 (PLC10)

The colloidal silica dispersions NISSAN ST-UP and SILCO Li-518 were mixed in a 7:3 ratio (w/w) based on weight, diluted to 3 weight percent solids with water, and acidified with 3 M HNO₃ to a pH of 2.

### Primer Layer Coating Composition 11 (PLC11)

The colloidal silica dispersions NISSAN ST-UP and SILCO Li-518 were mixed in a 7:3 ratio (w/w) based on weight, diluted to 5 weight percent solids with water, and acidified with 3 M HNO₃ to a pH of 2.

### Primer Layer Coating Composition 12 (PLC12)

The colloidal silica dispersion NALCO 1115 was diluted to 0.5 weight percent solids with water, and acidified with 3 M HNO₃ to a pH of 2.

### Primer Layer Coating Composition 13 (PLC13)

A mixture was prepared by combining NALCO 1115 and NALCO DVSZN004 in a weight ratio (w/w) of 50:50 and diluting with water to 3 weight percent solids. The dispersion was acidified with 1.5 M HNO₃ to a pH of 2.5.

### Fluorinated Layer Coating Composition 1 (FLC1)

PPFO-disilane was diluted with 3M NOVEC ENGINEERED FLUID 7100 to prepare a 0.5 weight percent solution of fluorinated silane.

### Fluorinated Layer Coating Composition 2 (FLC2)

The fluorinated silanes HFPO-Silane and PFPO-Disilane were mixed at a 90:10 ratio (w/w) by weight and diluted with 3M NOVEC ENGINEERED FLUID 7100 to prepare a 0.5 weight percent solution of fluorinated silane.

### Fluorinated Layer Coating Composition 3 (FLC3)

PPFO-Disilane was diluted with 3M NOVEC ENGINEERED FLUID 7200DL to prepare a 0.5 weight percent solution of fluorinated silane.

### Fluorinated Layer Coating Composition 4 (FLC4)

The fluorinated silane CF₃OC₂F₄OC₂F₄OCF₂CONHC₃H₆Si(OEt)₃ was dissolved in 3M NOVEC ENGINEERED FLUID 7100 to prepare a solution containing 0.5 weight percent fluorinated silane.

### Fluorinated Layer Coating Composition 5 (FLC5)

A mixture was prepared by combining 10 parts by weight PPFO-Disilane, 60 parts by weight tetraethoxysilane (TEOS), and 30 parts by weight ethanol. Then 0.5 parts by weight of the mixture were diluted with 99.5 parts by weight 3M NOVEC ENGINEERED FLUID 7500.

### Fluorinated Layer Coating Composition 6 (FLC6)

The fluorinated silane CF₃OC₂F₄OC₂F₄OCF₂CONHC₃H₆Si(OEt)₃ and the crosslinker BTEOSE were mixed in weight ratio (w/w) of 88:12 and diluted with 3M NOVEC ENGINEERED FLUID 7100 to prepare a solution with 0.5 weight percent of the combined fluorinated silane and crosslinker.

### Fluorinated Layer Coating Composition 7 (FLC7)

The fluorinated silane PPFO-disilane and the crosslinker PDES were mixed in a weight ratio (w/w) of 70:30 and diluted with 3M NOVEC ENGINEERED FLUID 7100 to prepare a solution with 0.5 weight percent of the combined fluorinated silane and crosslinker.

### Fluorinated Layer Coating Composition 8 (FLC8)

(Heptafluoro-1,1,2,2-tetrahydrodecyl)dimethylchlorosilane was diluted with 3M NOVEC ENGINEERED FLUID 7200DL to prepare a 0.2 weight percent solution of hydrocarbon silane.

### Fluorinated Layer Coating Composition 9 (FLC9)

(Tridecafluoro-1,1,2,2-tetrahydrooctyl)dimethylchlorosilane was diluted with 3M NOVEC ENGINEERED FLUID 7200DL to prepare a 0.2 weight percent solution of hydrocarbon silane.

### Fluorinated Layer Coating Composition 10 (FLC10)

(Heptafluoro-1,1,2,2-tetrahydrodecyl)trichlorosilane was diluted with 3M NOVEC ENGINEERED FLUID 7200DL to prepare a 0.2 weight percent solution of hydrocarbon silane.

### Examples 1-6 and Comparative Example A

For each of Examples 1 to 6, a separate glass plate having dimensions of 5.1 cm by 7.6 cm was submerged into a sulfuric acid and hydrogen peroxide cleaning solution (the volume ratio (v/v) of sulfuric acid to hydrogen peroxide was 3:1) for 30 minutes. Afterwards, the glass plates were rinsed with deionized water and dried with a stream of nitrogen gas. Each glass plate was immersed in a primer layer coating composition (PLC) at a rate of 10.8 centimeters per minute (cm/min), held in the primer layer coating composition for 20 seconds, and removed from primer layer coating composition at a rate of 10.8 cm/min rate. Examples 1 to 6 were immersed respectively in PLC1 to PLC6. Each primer layer was dried at room temperature and then heated at 200° C. for 30 minutes. Each sample was subsequently dipped into a fluorinated layer coating composition (FLC1) using the same coating process used for the primer layer coating composition. Each sample was then dried at room temperature before a final heat treatment at 120° C. for 30 minutes.

For Comparative Example A, a glass plate was cleaned as described above for Examples 1-6. The glass plates were not dipped in a primer layer coating composition but only in FLC1.

The static, advancing (adv.), and receding (rec.) water (H₂O) and hexadecane (HD) contact angles for Examples 1-6 and Comparative Example A were measured using the measurement method described above. The results are summarized below in Table 1.

TABLE 1
Examples 1-6 and Comparative Example A

| | Primer | | | | | | |
|---|---|---|---|---|---|---|---|
| | Layer | | | | | | |
| | Coating | H₂O Contact | | | HD Contact | | |
| | Com- | Angle degrees | | | Angle, degrees | | |
| Example | position | Static | Adv. | Rec. | Static | Adv. | Rec. |
| 1 | PLC1 | 114 | 117 | 100 | 70 | 76 | 67 |
| 2 | PLC2 | 111 | 112 | 95 | 69 | 74 | 57 |
| 3 | PLC3 | 129 | 135 | 98 | 81 | 85 | 69 |
| 4 | PLC4 | 131 | 130 | 105 | 81 | 86 | 74 |
| 5 | PLC5 | 120 | 114 | 85 | 72 | 78 | 58 |
| 6 | PLC6 | 134 | 142 | 106 | 93 | 94 | 79 |
| Comp. A | None | 113 | 119 | 95 | 70 | 76 | 58 |

### Examples 7-12 and Comparative Example B

For each of Examples 7-10, a separate stainless steel coupon with dimensions of 5.1 cm by 7.6 cm was submerged into a sulfuric acid and hydrogen peroxide cleaning solution (the volume ratio (v/v) of sulfuric acid to hydrogen peroxide was 3:1) for 120 minutes. Afterwards, each stainless steel coupon was rinsed with deionized water and dried with a stream of nitrogen gas. Each stainless steel coupon was immersed in a primer layer coating composition (PLC) at a rate of 11.5 centimeters per minute (cm/min), held in the primer layer coating composition for 30 seconds, and then removed from primer layer coating composition at a rate of 11.5 cm/min rate. Examples 7, 8, 10, 11, and 12 were immersed in PLC9 and Example 9 was immersed in PLC7. Each primer layer was dried at room temperature and then heated at 150° C. for 10 minutes. Each sample was subsequently dipped into fluorinated layer coating composition as indicated in Table 2. The same coating process used for the primer layer coating composition was used for the fluorinated layer coating composition. Each sample was then dried at room temperature before a final heat treatment at 120° C. for 10 minutes. Upon cooling to room temperature the surfaces of the samples were cleaned with a paper towel moistened with 3M NOVEC ENGINEERED FLUID 7100.

For Comparative Example B, the stainless steel coupon was cleaned in a similar manner, but no primer layer coating was applied. The stainless steel coupon was dipped only in a fluorinated layer coating composition (FLC2).

Static, advancing (adv.), and receding (rec.) water (H₂O) contact angles for Examples 7-12 and Comparative Example B were measured using the method for measuring contact angles described above. The results are reported below in Table 2 as the initial contact angle. Samples of Examples 7-12 and Comparative Example B were then subjected to abrasion testing using Abrasion Testing—Method 1 described above for 200, 2000, 5000 or 10000 cycles. Static, advancing (adv.), and receding (rec.) water (H₂O) contact angles for Examples 7-12 and Comparative Example B were measured on the abrasion tested samples using the method for measuring contact angles described above. The contact angle results after each abrasion tests are reported below in Table 2. The contact angle data for the Comparative Example B was obtained only after 200 abrasion cycles.

TABLE 2
Examples 7-12 and Comparative Example B

| | Fluorinated | H₂O Contact Angle [Standard Deviation], degrees | | | | |
|---|---|---|---|---|---|---|
| | Layer | | | After 2000 | After 5000 | After 10000 |
| | Coating | | | Abrasion | Abrasion | Abrasion |
| Example | Composition | | Initial | Cycles | Cycles | Cycles |
| 7 | FLC1 | Static | 111.1 [0.3] | | 111.4 [0.6] | 113.2 [1.2] |
| | | Adv. | 115.1 [1.2] | | 111.6 [1.0] | 114.4 [0.9] |
| | | Rec. | 91.7 [1.4] | | 93.3 [3.3] | 92.4 [1.5] |
| 8 | FLC4 | Static | 117.3 [3.8] | | 112.8 [0.6] | 111.2 [0.9] |
| | | Adv. | 116.5 [4.8] | | 112.9 [1.5] | 114.4 [1.2] |
| | | Rec. | 100.9 [1.0] | | 102.9 [1.9] | 103.5 [0.3] |
| 9 | FLC2 | Static | 119.0 [0.7] | | 103.3 [3.3] | 108.3 [1.7] |
| | | Adv. | 118.7 [1.3] | | 106.6 [6.2] | 107.9 [3.1] |
| | | Rec. | 105.3 [3.9] | | 90.8 [2.3] | 91.1 [2.6] |
| 10 | FLC6 | Static | 103.8 [0.3] | 107.7 [1.3] | | |
| | | Adv. | 107.1 [1.3] | 109.0 [2.0] | | |
| | | Rec. | 95.4 [3.0] | 107.7 [1.3] | | |
| 11 | FLC5 | Static | 104.0 [1.9] | 107.0 [1.1] | | |
| | | Adv. | 106.9 [1.3] | 108.8 [1.8] | | |
| | | Rec. | 92.7 [2.2] | 107.0 [1.1] | | |
| 12 | FLC7 | Static | 102.2 [1.2] | 103.9 [0.7] | | |
| | | Adv. | 103.8 [1.5] | 103.9 [2.1] | | |
| | | Rec. | 82.9 [1.4] | 103.9 [0.7] | | |
| Comp. B | FLC1 | Static | 116.0 [0.6] | 87.7 [1.3] | | |
| | | Adv. | 117.1 [1.8] | 91.3 [1.1] | | |
| | | Rec. | 75.7 [2.4] | 42.4 [1.9] | | |

### Examples 13 and Comparative Example C

Several 50 micrometer thick PET films were coated with a primer layer coating composition (PLC13) using a #6 Meyer bar. The typical dry coating thickness was in the range of 0.15 to 0.20 micrometers. The primer layer coatings were dried at room temperature before being heated 5 minutes at 120° C.

For Example 13, the primer layer coated PET film was coated with a fluorinated layer coating composition (FLC3) using a #6 Meyer bar. The coated films were dried at room temperature before a final heat treatment of 120° C. for 10 minutes. Upon removal from the oven the films were wiped with a paper towel and HFE 7200DL three times.

For Comparative Example C, the PET film was coated with the primer layer coating (PCL13) but not with FLC3.

Example 13 and Comparative Example C were abrasion tested according to Abrasion Testing—Method 2. The water contact angles were measured before and after abrasion as shown below in Table 3.

TABLE 3
Example 13 and Comparative Example C

| | Fluorinated Layer | | | After 300 Abrasion |
|---|---|---|---|---|
| | Coating | | Initial [Standard | Cycles [Standard |
| Example | Composition | Contact Angle | Deviation], degrees | Deviation], degrees |
| 13 | FLC3 | Static | 110.5 [0.5] | 110.3 [1.7] |
| | | Advancing | 110.6 [0.5] | 110.6 [2.2] |
| | | Receding | 79.5 [1.5] | 78.6 [3.3] |
| Comp. C | None | Static | 9.3 [1.2] | 16.2 [2.4] |
| | | Advancing | 9.5 [0.8] | 17.6 [2.7] |
| | | Receding | 9.0 [1.6] | 9.9 [1.3] |

### Examples 14-20 and Comparative Example D-F

For each of Examples 14-16, a separate glass slide having dimensions of 2.5 cm by 7.5 cm was cleaned with a slurry of ALCONOX powder. Afterwards, the glass plates were rinsed with deionized water and dried with a stream of nitrogen gas. Each glass plate was immersed in a primer layer coating composition (PLC10) at a rate of 40 cm/min, held in the primer layer coating composition for 60 seconds, and then removed from primer layer coating composition at a rate of 40 cm/min rate. Each primer layer was dried at room temperature and then heated at 120° C. for 10 minutes. Each sample was subsequently dipped into fluorinated layer coating composition (FLC8 to FLC10 as indicated in Table 4), held in the fluorinated layer coating composition for 5 minutes, and then removed from the fluorinated layer coating composition. Each sample was then dried at room temperature for 10 minutes before rinsing with methanol After the samples were dried again at room temperature, they were treated with a final heat treatment at 120° C. for 15 minutes.

For Comparative Examples D-F, glass plates were cleaned as described above for Examples 14-16. The glass plates were not dipped in a primer layer coating composition but only in FLC8-FLC10 as indicated in Table 4.

For examples 17-19, PET film was coated with a gravure roll coater (#110 roll), 10 feet per minute line speed, ovens (three ovens that were each 1 meter long) set at 120° C. with primer layer coating composition (PLC11). The primed PET was cut into pieces with dimensions of 5.0 cm×10 cm. Each sample was subsequently dipped into fluorinated layer coating composition (FLC8 to FLC10 as indicated in Table 4), held in the fluorinated layer coating composition for 5 minutes, and then removed from the fluorinated layer coating composition. Each sample was then dried at room temperature for 10 minutes before rinsing with methanol After the samples were dried again at room temperature they were treated with a final heat treatment at 120° C. for 15 minutes.

For Example 20, a stainless steel coupon having dimensions of 5 cm by 10 cm was cleaned with a slurry of ALCONOX powder. Afterwards, the stainless steel coupon was rinsed with deionized water and dried with a stream of nitrogen gas. Each coupon was immersed in a primer layer coating composition (PLC10) at a rate of 40 cm/min, held in the primer layer coating composition for 60 seconds, and then removed from primer layer coating composition at a rate of 40 cm/min rate. The primer layer was dried at room temperature and then heated at 120° C. for 10 minutes. The sample was subsequently dipped into a fluorinated layer coating composition (FLC9), held in the fluorinated layer coating composition for 5 minutes, and then removed from the fluorinated layer coating composition. The sample was then dried at room temperature for 10 minutes before rinsing with methanol After the samples was dried again at room temperature, it was treated with a final heat treatment at 120° C. for 15 minutes.

The static, advancing (adv.), and receding (rec.) water (H₂O) contact angles for Examples 14-20 and Comparative Example D-F were measured using the measurement method described above. The results are summarized below in Table 4.

TABLE 4
Examples 14-20 and Comparative Example D-F

| | | | Fluorinated | | | |
|---|---|---|---|---|---|---|
| | | Primer Layer | Layer | H₂O Contact | | |
| | | Coating | Coating | Angle, degrees | | |
| Example | Substrate | Composition | Composition | Static | Adv. | Rec. |
| 14 | Glass | PLC10 | FLC8 | 102 | 107 | 58 |
| 15 | Glass | PLC10 | FLC9 | 95 | 102 | 51 |
| 16 | Glass | PLC10 | FLC10 | 134 | 138 | 111 |
| 17 | PET | PLC11 | FLC8 | 112 | 117 | 64 |
| 18 | PET | PLC11 | FLC9 | 107 | 115 | 58 |
| 19 | PET | PLC11 | FLC10 | 134 | 140 | 113 |
| 20 | SS | PLC10 | FLC9 | 111 | 115 | 60 |
| Comp. D | Glass | None | FLC8 | 68 | 70 | 57 |
| Comp. E | Glass | None | FLC9 | 70 | 74 | 64 |
| Comp. F | Glass | None | FLC10 | 114 | 123 | 93 |

### Example 21

For Example 21, a stainless steel coupon with dimensions of 5.1 cm by 7.6 cm was submerged into a sulfuric acid and hydrogen peroxide cleaning solution (the volume ratio (v/v) of sulfuric acid to hydrogen peroxide was 3:1) for 120 minutes. Afterwards, the stainless steel coupon was rinsed with deionized water and dried with a stream of nitrogen gas. The stainless steel coupon was immersed in a primer layer composition (PLC12) at a rate of 11.5 centimeters per minute (cm/min), held in the primer layer composition for 30 seconds, and removed from primer layer composition at a rate of 11.5 cm/min rate. The primer layer was dried at room temperature and then heated at 150° C. for 10 minutes. The sample was subsequently dipped into a fluorinated layer coating composition (FLC10) as indicated in Table 5), held in the fluorinated coating layer coating composition for 5 minutes, and then removed from the fluorinated layer coating composition. The sample was then dried at room temperature for 10 minutes before rinsing with methanol. After drying again at room temperature, the same was heated at 120° C. for 15 minutes.

Static, advancing (adv.), and receding (rec.) water (H₂O) contact angles for Example 21 was measured using the method for measuring contact angles described above. The results are reported below in Table 5 as the initial contact angle. Samples were then subjected to abrasion testing using the Abrasion Testing—Method 1 described above for 5,000 or 10,000 cycles. Static, advancing (adv.), and receding (rec.) water (H₂O) contact angles for Examples 21 were measured on the abrasion tested samples using the method for measuring contact angles described above. The contact angle results after each abrasion tests are reported below in Table 5.

TABLE 5
Example 21

| | | | H₂O | | | After |
|---|---|---|---|---|---|---|
| | Primer Layer | Fluorinated Layer | Contact | | After 5000 | 10000 |
| | Coating | Coating | Angle, | | Abrasion | Abrasion |
| Example | Composition | Composition | degrees | Initial | Cycles | Cycles |
| 21 | PLC12 | FLC10 | Static | 119 | 117 | 114 |
| | | | Advancing | 121 | 122 | 117 |
| | | | Receding | 103 | 104 | 98 |

1-16. (canceled)

17. An article comprising:
(a) a substrate:
(b) a hydrophobic coating comprising
(1) a primer layer attached to a surface of the substrate, the primer layer comprising a plurality of acid-sintered silica nanoparticles arranged to form a three-continuous dimensional porous network, wherein the primer layer comprises 85 to 99 weight percent silica nanoparticles and is dried product of primer layer coating composition comprising a silica sol acidified with an acid having a pKa less than 3.5 to a pH in a range of 2 to 5, the primer layer coating composition being free of a coupling agent having a plurality of reactive silyl groups; and
(2) a hydrophobic fluorinated layer attached to the primer layer, the hydrophobic fluorinated layer comprising a reaction product of a fluorinated silane with a surface of the acid-sintered silica nanoparticles in the primer layer, wherein the fluorinated silane has a reactive silyl group and a hydrophobic fluorinated group and wherein the wherein the hydrophilic coating withstands 300 cycles of abrasion using Abrasion Testing—Method 2.

18. The article of claim 17, wherein the fluorinated group is a perfluorinated group.

19. The article of claim 17, wherein the fluorinated silane is of Formula (I) 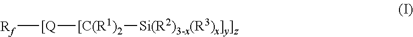
wherein
R_{f} is a z-valent radical of a polyfluoroether. polyfluoropolyether, or perfluoroalkane;
Q is a divalent or trivalent linking group;
each R¹ is independently hydrogen or alkyl;
each R² is independently hydroxyl or a hydrolyzable group;
each R³ is independently a non-hydrolyzable group;
each x is an integer equal to 0, 1, or 2;
y is an integer equal to 1 or 2; and
z is an integer equal to 1 or 2.

20. The article of claim 19, wherein Q comprises an alkylene.

21. The article of claim 19, wherein Q comprises at least one alkylene and further comprises at least one oxy, thio, —NR⁴—, methine, tertiary nitrogen, quaternary nitrogen, carbonyl, sulfonyl, sulfiryl, carbonyloxy, carbonylthio, carbonylimino, sulfonylimino, oxycarbonyloxy, iminocarbonylimino, oxycarbonylimino, or a combination thereof, wherein R⁴ is hydrogen, alkyl, aryl, or aralkyl.

22. The article of claim 17, wherein the silica nanoparticles are a mixture of spherical and acicular nanoparticles.

23. The article of claim 17, wherein the fluorinated silane is of Formula (Ia).

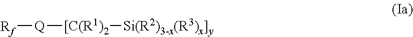

24. The article of claim 17, wherein the fluorinated silane is of Formula (Ib).

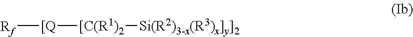

25. The article of claim 17, wherein the article is anti-reflective.

26. The article of claim 17, wherein the substrate is a polymeric material.

27. The article of claim 17, wherein the substrate transmits at least 85 percent of incident light in the visible region.

28. The article of claim 17, wherein the primer layer is free of an organic binder.

29. The article of claim 17, wherein the silica nanoparticles have an average specific surface area equal to at least 150 m²/gram.
